(19) United States
(12) Patent Application Publication
(10) Pub. No.: US 2026/0319481 A1
(43) Pub. Date: Oct. 15, 2026

(54) COMPUTER SYSTEM AND METHOD FOR OUTPUTTING DATA FOR DEFINING A COMPONENT FOR GUIDING ELECTROMAGNETIC WAVES

(71) Applicant: WAVE PHOTONICS LTD, Cambridge (GB)

(72) Inventors: James Patrick Lee, Cambridge (GB); Matthew Anderson, Cambridge (GB); Mateusz Witold Kubica, Cambridge (GB)

(73) Assignee: WAVE PHOTONICS LTD, Cambridge (GB)

(21) Appl. No.: 19/485,612

(22) PCT Filed: May 20, 2024
(86) PCT No.: PCT/GB2024/051308

§ 371 Date: Nov. 18, 2025

(30) Foreign Application Priority Data
May 19, 2023 (GB) 2307535.1

(51) Int. Cl. G05B 19/418

(52) U.S. Cl. CPC G05B 19/41885; G05B 2219/49004

(57) ABSTRACT

A computer system is presented for outputting data for defining a component for guiding electromagnetic waves. A fabrication process model is generated using data measured from one or more outputs of a physical fabrication process. First and second component model are generated by applying the fabrication process model to an initial configuration, of the component. The first and second models of the component each comprise one or more data values associated with one or more physical parameter data values of the initial configuration. At least one of the data values of the first model of the component is associated at least one of the physical parameter data values and is different to the corresponding data value, of the same physical parameter, of the second model of the component. A computer-modelled electromagnetic field output is generated for the first and second models. The outputs are compared to a common pre-defined electromagnetic field output. The data is output based on the comparisons.

### FIELD OF THE INVENTION

The field of the present invention is computer systems for electromagnetic components, in particular, but not limited to systems and methods for designing integrated waveguides.

### BACKGROUND

Integrated photonics is a technology which uses the same complementary metal-oxide semiconductor (CMOS) compatible fabrication processes, which are used in building integrated circuits, to build circuits which guide and manipulate light instead. The design of individual physical devices which collectively comprise a photonic integrated circuit (PIC) is typically done in a very labour intensive and manual approach, which often does not account for variations induced by the semiconductor fabrication process. Due to various reasons, such as substrate wafer quality, chemical etching and process variations, there are variations in the physical devices which are both systematic (e.g., how high spatial features are resolved in a photolithographic process) and non-systematic (e.g., local resist etching effects or wafer height variation, which are due to chemical interactions). Inverse design is a novel technique which may instead be used to optimise the design of a physical device computationally. During this optimisation, methods can be applied to increase the robustness/tolerance of the resulting device designs to possible fabrication variations.

Conventional integrated photonic device design methods are based on empirically determining the physical device design from principles of physics and guided mode optics. Parameter sweeps of these devices are usually explored in a simulation environment whereby it is common to solve Maxwell's electromagnetic (EM) field equations numerically to determine an operation of the device, until such a point where the desired operation of the device achieved. Performing parameter sweeps involves either manually adjusting parameters and re-running the EM field simulations or performing sweeps automatically through scripting with a computer program and the EM field solver.

Inverse design is an approach which uses computational optimisation to compute a physical device design algorithmically based on a desired operation of the device in a simulation environment. The general procedure of inverse design is to start from a target operational performance of a physical device in response to an optical signal received at one or more inputs. A loss function which relates the target performance, and the simulated performance (obtained through a simulation of the physical device) can then be defined based on the parameters used to define the physical device design, to be used in an optimisation algorithm. The goal of the optimisation is to minimise/maximise this loss function. The loss function can be anything to do with how the target EM field should be spatially/temporally when compared with the current calculated EM field in the regions of interest. This can take a variety of forms but will typically involve some calculation of EM field overlaps between the target EM fields and output EM fields (resulting from the EM simulation of the physical device). The loss function can also include any number of terms or be structured in any number of ways which act to constrain the optimisation path. This could include, but is not limited to, terms to penalise feature size/radius of curvature in the physical device design, terms to penalise EM fields in certain areas of the simulation domain, structure to bound loss function variance.

Optimisation of the physical device design is performed using the calculated value of the loss function after running a simulation to obtain the EM field values at the regions of interest, for a given set of parameter values. The regions of interest where the output EM field values are considered are typically specified by “monitors” in the simulation. The optimisation problem can be either constrained/unconstrained, global/local (or any hybrid approach) and the optimisation can be to maximise/minimise the loss function. Methods of optimisation can be gradient (e.g., gradient descent, conjugate-gradient, MMA, LBFGS) or non-gradient based (e.g., genetic, particle swarm, direct binary search). Gradient-based methods require evaluating the gradient of the loss function with respect to its arguments, the physical device design parameters, which can be done using various techniques. A common numerical method is to calculate the finite-difference gradient, which requires running as many simulations as number of degrees of freedom (DOF). The finite-difference method calculates the gradient by perturbing each parameter value independently and performing another simulation to obtain a new value for the loss function. Using the previous unperturbed result for the loss function and the new value determined after a small perturbation to the parameter, it is possible to determine the gradient of the loss function with respect to that parameter. Another way is to use the adjoint method, which is a numerical method to efficiently determine the gradient of a function or operator. In this this context, the adjoint method can be applied by defining an adjoint simulation. In the adjoint simulation, EM field monitors at the regions of interest are replaced by EM current sources with an amplitude and phase based on the derivative of the loss function with respect to the EM fields from the “forward” simulation run, which was used to calculate the value of the loss function. The simulated adjoint EM current sources give rise to the simulated adjoint EM fields in the adjoint simulation. The adjoint simulation is analogous to running the simulation “backwards” or backpropagating the target output through the simulation. In the context of determining gradients, backpropagation refers specifically to the process of computing the gradients of the loss function. In the adjoint method described here, the gradient of the loss function with respect to each design parameter can be related to an inner product involving the adjoint EM field and the EM field. As the EM field values from the “forward” and “backward” simulations are used to calculate the gradients of the loss function with respect to its parameters, only two EM field simulations are required to determine the gradients of the loss function with respect to all design parameters. This method makes available the parametrisations of physical device design with many DOF that would be unfeasible in a finite-difference method, due to the computational time required to complete gradient calculations. Another approach to determine the gradients is to perform automatic differentiation on the code of the forward simulation and calculate the gradients during the execution of the backward pass. This is very similar to the backpropagation method.

An example of one implementation of the inverse design method is detailed in the journal article Christopher M. Lalau-Keraly, Samarth Bhargava, Owen D. Miller, and Eli Yablonovitch, “Adjoint shape optimization applied to electromagnetic design”, Opt. Express 21, 21693-21701 (2013). In this implementation, which is typical for inverse design, the adjoint method was used to optimise the shape of a symmetric Y-splitter on a silicon-on-insulator (SOI) material system comprising a silicon dioxide cladding and intrinsic silicon as the active layer. The symmetric Y-splitter is a device which takes the light power in the fundamental mode at one input and splits it evenly into two spatially separated outputs. The design was parameterised using a level-set method to define two regions of permittivity (or refractive index). In this example, two distinct values were defined for regions of silicon, with permittivity ϵ₁, and regions of the silicon dioxide cladding, with permittivity ϵ₂. The parameters of the level-set function used to define the physical device design were then optimised with an adjoint-gradient-steepest-descent algorithm, using the finite-difference time-domain method (FDTD) to perform the simulations of the physical device. The device was first optimised in 2D using the effective index method and then later optimised in 3D.

A similar example is shown in Andrew Michaels and Eli Yablonovitch, “Leveraging continuous material averaging for inverse electromagnetic design,” Opt. Express 26, 31717-31737 (2018), where the authors implement inverse design using the adjoint method to design a physical device which tapers the width of a waveguide from an initial width w₁ to a final width w₂. The physical device design in this case is defined by piecewise linear functions (i.e., polygons). The vertices of the polygons, pairs of (x,y) coordinates on a cartesian plane, are used as design parameters for the optimisation algorithm. A boundary smoothing routine, common to many implementations of the FDTD method, is used to enable accurate gradient calculation with respect to the changing position of the polygon vertices. This work does consider a radius of curvature constraint on the design, which is related to fabrication tolerances for minimum feature sizes, however, it is not extensive, and the work does not take into account robustness to variations in a fabrication process.

In general, the initial design of a physical device is defined by specifying the permittivity (or refractive index) values of discrete simulation domain elements (usually voxels for grid-based algorithms such as FDTD). Values can be real or complex depending on whether the material is non-dispersive or dispersive, respectively. In the context of inverse design for integrated photonics, the material permittivity values correspond to those materials used in the fabrication process. Typically, this will be a material “core” and “cladding” but is not limited to this. Permittivity/refractive index values are typically taken from measured data available in literature sources. Methods are typically used to provide the illusion of continuity of the permittivity through interpolation across simulation domain elements. Illusion of continuity here refers to a smooth change of the permittivity in the simulation domain elements from values of permittivity which correspond to different materials of the geometry. Such methods are used to reduce error (and achieve quadratic error convergence) in the EM simulation resulting from the discretisation in the numerical calculation which can result in unphysical numerical artifacts (e.g., infinite fields at an interface).

There are many ways in which the initial design may specify the permittivity values, some definitions may come from pre-determined physical device designs (such as a physics-based design used in traditional integrated photonics, typically constructed from various polygon shapes). Many ways of parameterisation exist for polygon-defined designs. This can include, among others, cartesian coordinates of the polygon vertices, k-degree splines/B-splines, level-set functions, and any other methods of defining curvilinear shapes in a 2D plane. The parameterisation is restricted to a 2D plane in this context as only discrete values in the third (height) dimension are specified. E.g., for a typical integrated photonics process there can be partial etches or a full etch to define discrete thicknesses of the active layer, such as those used to define grating couplers or rib waveguides (partial etches) as well as the strip waveguides (full etch). This is not an optimisable parameter. While performing quasi-3D simulations in 2D using the effective index method, different active layer thicknesses of the “core” material can be modelled continuously as a continuous change in the effective refractive index, however, this is still not an optimisable parameter.

Another parameterisation is to simply use the values of the simulation domain elements themselves. This is the case for topology optimisation (TO) methods where every “pixel” (in a 2D example) is a design parameter, leading to typically thousands or millions of parameters being optimised over. An example of TO in the context of integrated photonics physical device design is implemented in the journal article Alec M. Hammond, Ardavan Oskooi, Steven G. Johnson, and Stephen E. Ralph, “Photonic topology optimization with semiconductor-foundry design-rule constraints,” Opt. Express 29, 23916-23938 (2021). In this work, several example physical device designs are optimised using the adjoint method. The fabrication tolerance of the resulting design is addressed in this work by adding a constraint to the optimiser which includes manufacturing design-rule constraints, which restrict certain features in the end design such as minimum area, minimum enclosed area, curvature, and linewidth. In this work, fabrication tolerance is only accounted for in the form of a feature constraint/penalty to the loss function. This can be problematic in that a design which adheres to the design rules yet may still be subject to variation from the fabrication process, and subject then to a reduction in robustness.

TO physical device designs also typically have non-intuitive curvilinear shapes with many interfaces between the core regions and the cladding regions. This can lead to problems in the resulting designs, even when fabrication constraints are imposed. The reason being that a major performance loss in a real fabricated device is attributed the scattering of light at these interfaces, due to the roughness of the interface resulting the fabrication process. The roughness of this interface can be on length scales from micrometres down to nanometres. Many interfaces can result in a significant amount of undesired light scattering, a feature which is not considered in the simulation and optimisation procedure.

The work described in Guowu Zhang, Dan-Xia Xu, Yuri Grinberg, and Odile Liboiron-Ladouceur, “Topological inverse design of nanophotonic devices with energy constraint,” Opt. Express 29, 12681-12695 (2021) attempts to account for this effect by introducing a penalty term to the loss function. The penalty term here, the so-called energy constraint, attempts to impose the condition that most of the EM energy in the simulation is contained within the core regions. It is claimed that this reduces areas in the final design of the EM fields crossing interfaces.

There are various methods to include fabrication process variation effects, such as the width and height variation of the etched substrate, when simulating the physical device. A typical method used to account for some process variation is to consider a “corner analysis”. This refers to method of determining what the “worst-case” scenario is, e.g., maximum height and width variations of a waveguide cross-section on a given process, then perform five simulations (one at each ‘corner’, and then the desired value). This method aims to provide information on this worst-case scenario, such that they can be considered during the design/optimisation process. In general, a corner analysis can be applied to an arbitrary number of parameters which can be varied and result in a change to the physical device design.

U.S. Ser. No. 11/476,964B2 and U.S. Ser. No. 11/196,503B2 describe related methods, techniques of robust inverse design that account for manufacturing variability due to operating conditions. The methods outlined in these patents comprises two elements. The first element is performing inverse design of a physical device by considering a plurality of variations of the physical device design resulting from changes to operating conditions. Operating conditions refer to at least one of; ambient temperature, erosion, dilation, waveguide thickness, structure out of plane, sidewall angle, surface roughness, misalignment, optical aberrations, and material imperfections. At each iteration of the optimisation, a plurality of designs is simulated, each under an independent assumed set of operating conditions, by sampling independently from sets of pre-determined values for the operating conditions. A loss function is evaluated for each separate simulation and is subsequently combined into a single loss function value. The gradient of the parameters of loss function is determined through the adjoint method and backpropagation. The second element is performing inverse design of a physical device by considering a fabrication model and a perturbation model. The fabrication model is trained to determine how perturbations of the operating conditions will affect the physical device design. The perturbation model combines the result of the fabrication model with the simulation EM field values to determine a penalty to the loss function related to the robustness of the design to the perturbations of the operation conditions. Only a single physical device design is simulated at each iteration of the optimisation. The gradients of the loss function parameters are determined by the adjoint method and backpropagation. In both cases the design is optimised by a gradient-based optimisation algorithm. However, no methods are described in this context on how a particular fabrication model simulate the fabrication of a physical device when considering a particular set of operating conditions for the fabrication of the physical device.

The work in X. Wang et al., “Lithography simulation for the fabrication of silicon photonic devices with deep-ultraviolet lithography,” The 9th International Conference on Group IV Photonics (GFP), San Diego, CA, USA, 2012, pp. 288-290, doi: 10.1109/GROUP4.2012.6324162 details a method to account for the fabrication process effects by simulating fabrication of the physical device based on the parameters of the optical source/optical setup used for the photolithography. In this method, properties of the optical source, such as the spatial shape, wavelength, numerical aperture etc are used to compute a matrix transform operator description of the photolithography process. This transform was applied to a physical device design to simulate the expected fabricated physical device. Simulations were then performed on the as fabricated physical device.

US patent US20210266088A1 describes techniques for inverse design of physical devices in the context of generating designs for photonic integrated circuits (including a multichannel photonic demultiplexer). In some embodiments, an initial design of the physical device is received, and a plurality of sets of operating conditions for fabrication of the physical device are determined. In some embodiments, the performance of the physical device as fabricated under the sets of operating conditions is simulated, and a total performance loss value is backpropagated to determine a gradient to be used to update the initial design. In some embodiments, instead of simulating fabrication of the physical device under the sets of operating conditions, a robustness loss is determined and combined with the performance loss to determine the gradient.

US patent 2020226221A1 describes a method and system for optimizing structural parameters of an electromagnetic device that includes performing operations, where the operations include performing a time-forward simulation of a field response in a simulated environment describing the electromagnetic device and extracting decomposition components from the field response to compute a loss value.

### SUMMARY

In first aspect, there is present a computer system (2) for outputting data (4) for defining a component (6); the component for guiding electromagnetic waves;
the computer system (2) comprising one or more modules (8) configured to:
I) generate a fabrication process model (10) using data (12) measured from one or more outputs of a physical fabrication process (14) suitable for forming the component (6);
II) generate at least a first model (16, MODEL 1) of the component (6) by applying the fabrication process model (10) to an initial configuration (20, CONFIG. 1) of the component (6); wherein:
   i) the initial configuration (20) of the component (6) is associated with one or more physical parameter data values (22);
   ii) the first (16) model of the component (6) comprises one or more data values (19a, 19b) associated with the one or more physical parameter data values (22) of the initial configuration (20);
   iii) at least one of the said data values (19a) of the first model (16) of the component is associated at least one of the physical parameter data values (22);
II) determine (23), for the first model of the component, a computer-modelled electromagnetic field output (24a, 24b) of the first model for a given electromagnetic field input (26) to the first model;
III) compare (28), for the first model of the component, the respective electromagnetic field output (24a, 24b) to a pre-defined electromagnetic field output (30);
IV) output, based on the comparison, data (4) for defining the component (6); the output data associated with the physical parameters (22) of the initial configuration (20) of the component.

The above first aspect may be adapted according to any feature or configuration described herein, including, but not limited to, any one or more of the following optional features underneath. The first aspect may also be adapted according to features and configurations of other aspects herein, for example, the second aspect.

Optionally, the computer system is configured to:
i) determining a plurality of physical parameter data values for a physical parameter of the initial configuration;
ii) determining an average value of the plurality of physical parameter data values for the physical parameter;
iii) using the average value to generate the first model of the component.

Optionally, an average value may be generated using a plurality of respective physical parameter data values, for, a respective plurality, or all, of the physical parameters. Optionally, the fabrication model may comprise the average value such that an average fabrication model transformation is generated. Optionally, when the average fabrication model is applied, data corresponding to the average expected output of the fabrication process is generated.

Optionally, the system is configured such that the fabrication process model (10) comprises a computational parameter; the system is configured to determine at least a first and a second version of the computational parameter wherein at least one data value or property of the first version is different to the second version.

Optionally, the computation parameter is associated with a plurality of the one or more data values (19a, 19b) associated with the one or more physical parameter data values (22).

Optionally, the computation parameter is associated with a plurality of the one or more physical parameter data values (22).

Optionally, the first and second versions of the computational parameter give rise to one or more differences in a plurality of different physical parameter data values (22) of the initial configuration (20).

Optionally, the system is configured to determine an average version of the computational parameter.

Optionally, the average is a mean value.

Optionally, the computational parameter is associated with one or more data values.

Optionally, the fabrication process model (10) comprises a plurality of computational parameters.

Optionally, the system is configured such that the computation parameter is a kernel.

Optionally, the computer system is configured to:
I) generate a second model of the component by applying the fabrication process model (10) to the initial configuration (20, CONFIG. 1) of the component (6); wherein:
i) the second (18) model of the component (6) comprises one or more data values (19a, 19b) associated with the one or more physical parameter data values (22) of the initial configuration (20);
ii) at least one of the said data values (19a) of the first model (16) of the component is different to the corresponding data value (19b), of the same physical parameter, of the second model (18) of the component;
II) determine (23), for second model of the component, a computer-modelled electromagnetic field output (24a, 24b)) of the second model for a given electromagnetic field input (26) to the second model;
III) compare (28), for the second model of the component, the respective electromagnetic field output (24a, 24b) to the pre-defined electromagnetic field output (30); the EM field output being common to the comparison for the first and second models;
IV) outputting the data based on the comparisons.

Optionally, the system is configured such that:
the first model is generated using the first version of the computational parameter;
the second model is generated using the second version of the computational parameter.

Optionally, the system is configured such that the first model and second model differ in a plurality of the physical parameter data values (22) of the initial configuration (20).

Optionally the computer system may determine a sensitivity of a loss value.

Optionally the computer system may determine the sensitivity of the loss value based on a gradient of the composite loss value with respect to a plurality of data values and a gradient of the data values with respect to fabrication model parameters.

Related to the first aspect, there is further presented a computer implemented method for outputting data (4) for defining a component (6); the component for guiding electromagnetic waves;
the method comprising using one or more computer modules to:
I) generate a fabrication process model (10) using data (12) measured from one or more outputs of a physical fabrication process (14) suitable for forming the component (6);
II) generate at least a first model (16, MODEL 1) of the component (6) by applying the fabrication process model (10) to an initial configuration (20, CONFIG. 1) of the component (6); wherein:
i) the initial configuration (20) of the component (6) is associated with one or more physical parameter data values (22);
ii) the first (16) model of the component (6) comprise one or more data values (19a, 19b) associated with the one or more physical parameter data values (22) of the initial configuration (20);
iii) at least one of the said data values (19a) of the first model (16) of the component is associated at least one of the physical parameter data values (22);
II) determine (23), for the first model of the component, a computer-modelled electromagnetic field output (24a, 24b) of the first model for a given electromagnetic field input (26) to the first model;
III) compare (28), for the first model of the component, the respective electromagnetic field output (24a, 24b) to a pre-defined electromagnetic field output (30);
IV) output, based on the comparison, data (4) for defining the component (6); the output data associated with the physical parameters (22) of the initial configuration (20) of the component.

The above method may be adapted according to any feature or configuration described for the first aspect.

In a second aspect there is presented a computer system (2) for outputting data (4) for defining a component (6); the component for guiding electromagnetic waves;
the computer system (2) comprising one or more modules (8) configured to:
I) generate a fabrication process model (10) using data (12) measured from one or more outputs of a physical fabrication process (14) suitable for forming the component (6);
II) generate at least a first model (16, MODEL 1) of the component (6) and a second model (18, MODEL 2) of the component (6) by applying the fabrication process model (10) to an initial configuration (20, CONFIG. 1) of the component (6); wherein:
   i) the initial configuration (20) of the component (6) is associated with one or more physical parameter data values (22);
   ii) the first (16) and second (18) models of the component (6) each comprise one or more data values (19a, 19b) associated with the one or more physical parameter data values (22) of the initial configuration (20);
   iii) at least one of the said data values (19a) of the first model (16) of the component is:
      a) associated at least one of the physical parameter data values (22);
      b) different to the corresponding data value (19b), of the same physical parameter, of the second model (18) of the component;
II) determine (23), for each of the first and second models of the component, a computer-modelled electromagnetic field output (24a, 24b) of the respective model for a given electromagnetic field input (26) to the respective model of the component (6);
III) compare (28), for each of the first and second models of the component, the respective electromagnetic field output (24a, 24b) to a common pre-defined electromagnetic field output (30);
IV) output, based on the comparisons, data (4) for defining the component (6); the output data associated with the physical parameters (22) of the initial configuration (20) of the component.

The above second aspect may be adapted according to any feature or configuration described herein, including but not limited to any one or more of the following and/or the optional features for the first aspect above.

Optionally, the first and second models may be models from a first set of models.

Further sets of models may be generated for further initial configurations of the component. Each initial configuration is preferably different to other configurations.

Each set of models may comprise a plurality of models wherein a plurality may be three or more models, or two or more models.

Optionally, the computer system may be configured to:
a) determine (23), for each of the models of the component in the same set, a computer-modelled electromagnetic field output (24a, 24b) of the respective model for an electromagnetic field input (26) to the respective model of the component (6); the electromagnetic field input being common for each of the models;
b) compare (28), for each of the models of the component in the same set, the respective electromagnetic field output (24a, 24b) to a common pre-defined electromagnetic field output (30);
c) output the data for defining the component based on the comparisons.

Optionally, the first model (16, MODEL 1) of the component (6) and the second model (18, MODEL 2) may be generated using a generic model of the component that is associated with the initial configuration. The generic model of the component may use the fabrication process model or outputs from the fabrication process model to produce the first and second models.

The first and second models may be instances of the generic model wherein each instance uses different parameters output from the fabrication process model.

The generic model may be configured to output any of:
a) one or more graphical layouts of the component;
b) data defining the component of the respective model such that a module of the computer system may create a virtual version of the component in a virtual environment for EM simulation.

Optionally, the computer system may be configured to generate (30) one or more test patterns (32) for the physical fabrication process (14).

Optionally the one or more test patterns (32) are generated using a noise function.

Optionally, the computer system may be configured to generate the fabrication process model (10) using a plurality of outputs (12) from the physical fabrication process (14) wherein:
a) each output (12) is associated with a different test pattern (32);
b) each output comprises data of the measured shape of a physical feature of an output sample from the physical fabrication process (14).

Optionally, the computer system may be configured such that the fabrication process model generates the first model (16) and second model (18) using component feature dimension data derived from the measured data (12).

Optionally, the computer system may be configured such that the fabrication process model is a model generated by machine learning wherein the model is trained using the data measured from the one or more outputs of the physical fabrication process (14).

Optionally, the computer system may be configured such that the component feature dimension data comprises any one or more of:
a) a component dimension threshold;
b) a component dimension rule.

Optionally the rule may couple a plurality of the physical parameters. For example, the rule may couple multiple parameters of the component layout in a model. For example, as a side-wall slope angle tends away from perpendicular (with respect to the underlying substrate), the sidewall roughness may increase. Rules may therefore make data values for physical parameters dependent upon data values of other physical parameters. In some examples rules may be provided by a computational parameter such as a kernel that transforms an initial ‘ideal’ configuration into a model wherein changing the kernel affects one or more, preferably multiple physical parameters of the component.

Optionally, the computer system may be configured such that component feature dimension threshold comprises a minimum feature size.

Optionally, the minimum feature size may be a radius of curvature being half the minimum threshold size, corresponding to a curvature of the inverse of half the threshold size. E.g., if the minimum feature size was to be 200 nm, the magnitude of the curvature of any part of the component should be less than 1/100 nm⁻¹. Optionally, the minimum feature size corresponding to a minimum gap width or spacing.

Optionally, the minimum feature size corresponding to a minimum bridge width.

Optionally, the computer system may be configured to generate the component dimension rule from measured data (12).

The component dimension rule may correspond to a gap width or spacing.

The component dimension rule may correspond to a bridge width. The bridge width typically refers to a minimum dimension of a physical feature, for example a portion of core material forming a structure such as a waveguide.

Optionally, the data for defining the component may be generated by:
a) generating, for each of the first and second model, a loss value based on the comparison to the common pre-defined electromagnetic field output (30);
b) generating the data for outputting, using the loss value.

The loss value may be a figure of merit. The loss value may be associated with the: degree of overlap; and/or, or the degree of correlation, between the predefined EM field output and the EM field output of the respective model. The loss value may include any number of additional penalty terms relating to the fabricability of the component, e.g., such as determined from a minimum feature size.

Optionally the loss values may be combined to generate a composite loss value. The composite loss value may be used to:
a) generate the data for output; and/or
b) select the data for output;
c) generate a further initial configuration of the component to, in turn, generate a further first and further second model of the component.

Optionally, the comparison further comprises determining a sensitivity of the composite loss value with respect to the fabrication model parameters.

Optionally the computer system may determine a sensitivity of the loss values with respect to the fabrication. Optionally, the sensitivity comprises the gradient of the loss function with respect to the fabrication model parameters.

Optionally the loss function may be a differentiable function.

Optionally the computer system may determine a sensitivity of the composite loss value with respect to the fabrication model parameters.

Optionally the computer system may determine the sensitivity of the composite loss value with respect to the fabrication model parameters based on a gradient of the composite loss value with respect to a plurality of data values and a gradient of the data values with respect to fabrication model parameters.

Optionally the computer system may use the sensitivity of the loss values or composite loss values with respect to the fabrication model parameters as an indicator of the robustness of the fabrication model.

Optionally the computer system may include the sensitivity of the loss values or composite loss values with respect to the fabrication model parameters as part of the optimisation function for the fabrication model.

The data selected for output may be associated with one or more of the parameters of the component associated with the initial configuration.

Optionally, the data for defining the component may be generated using an inverse design process.

Optionally, the inverse design process may comprise the following steps:
a) Defining a target performance of the component, a corresponding loss function and initial data defining a component;
b) Calculating a loss value and gradient of the loss value with respect to the data defining the component for this structure by:
   i) Determine a computer modelled output EM field
   ii) Calculate the loss value using the output EM fields and the loss function
   iii) Define an adjoint simulation configuration based on the outputs of (i) and (ii)
   iv) Determine a computer modelled output EM of the adjoint simulation
   v) Calculate gradient of the loss value with respect to each of the data values which define the component using the outputs of (i)-(iv)
c) Adjust the data values defining the component based on the loss value and the gradients of the loss value determined in (b).
d) Repeat (a)-(c) as required by an optimisation algorithm until the loss value has converged to some desired minimum/maximum or threshold value.

Optionally, the computer system may be configured such that the data values (19a, 19b) associated with the one or more physical parameter data values (22) comprises any one or more of:
a) a value associated with a material property of the component;
b) a value associated with a physical dimension of the component.

Optionally, the computer system may be configured such that the material property comprises a refractive index.

Optionally, the computer system may be configured such that the physical dimension comprises any one or more of:
a) a length of the component along the direction of EM wave propagation through the component;
b) a width or depth of the component that is perpendicular to the direction of EM wave propagation through the component.
c) a radius of a circular component;
d) a major and minor axis, and/or two loci of, an elliptical component;
e) a general function defining the shape of an irregular component;
f) a test pattern used for training the fabrication model.

Optionally, the computer system may output the data (4) for input (34) into the physical fabrication process (14) wherein the physical fabrication process (14) is configured to generate (36) a physical sample of the component (6) using the output data (4).

Related to the second aspect there is presented, a computer implemented method for outputting data (4) for defining a component (6); the component for guiding electromagnetic waves;
the method comprising using one or more computer modules to:
   15) generate a fabrication process model (10) using data (12) measured from one or more outputs of a physical fabrication process (14) suitable for forming the component (6);
II) generate at least a first model (16, MODEL 1) of the component (6) and a second model (18, MODEL 2) of the component (6) by applying the fabrication process model (10) to an initial configuration (20, CONFIG. 1) of the component (6); wherein:
   iv) the initial configuration (20) of the component (6) is associated with one or more physical parameter data values (22);
   v) the first (16) and second (18) models of the component (6) each comprise one or more data values (19a, 19b) associated with the one or more physical parameter data values (22) of the initial configuration (20);
   vi) at least one of the said data values (19a) of the first model (16) of the component is:
      c) associated at least one of the physical parameter data values (22);
      d) different to the corresponding data value (19b), of the same physical parameter, of the second model (18) of the component;
II) determine (23), for each of the first and second models of the component, a computer-modelled electromagnetic field output (24a, 24b) of the respective model for a given electromagnetic field input (26) to the respective model of the component (6);
III) compare (28), for each of the first and second models of the component, the respective electromagnetic field output (24a, 24b) to a common pre-defined electromagnetic field output (30);
IV) output, based on the comparisons, data (4) for defining the component (6); the output data associated with the physical parameters (22) of the initial configuration (20) of the component.

There is also presented, in a third aspect, a method of forming a component for guiding electromagnetic waves, the method comprising:
a) generating output data (4) according to the computer implemented method of the first or second aspects;
b) inputting the data into the physical fabrication process (14) as described in the first or second aspect;
c) forming the component, using the physical fabrication process (14) and the said input data.

Optionally, the method may comprise:
a) forming a physical sample using a test pattern;
b) measuring the test pattern to determine the data.

There is further presented, in a fourth aspect, an apparatus for forming a component for guiding electromagnetic waves, the apparatus comprising:
a) a computer system as described in the first or second aspects;
b) a system for implementing the physical fabrication process (14) as described in the first or second aspects.

There is also presented, in a fifth aspect, a computer implemented method for outputting data for defining a fabrication process model for defining a component (6) made in a fabrication process (14); the component for guiding electromagnetic waves. The method may comprise using one or more computer modules to do one or more, preferably all of the following: A) receive a plurality of fabrication process models, wherein each of the plurality of fabrication process models comprises a set of one or more associated fabrication process model parameter data values, wherein each of the plurality of the fabrication process models is represented by a parameter space by its respective set of one or more fabrication process model parameter data values; B) perform principal component analysis on the one or more sets of fabrication process model parameter data values to determine at least a first principal component (1405), wherein the first principal component corresponds to a direction in the parameter space comprising the largest variance; C) determine a distribution of fabrication process model parameter data values along the at least first principal component; D) sample the distribution of fabrication process model parameter data values along the at least first principal axis to obtain at a plurality of samples of sets of fabrication process model parameter data values; E) output data representing the plurality of samples of sets of fabrication process model parameter data values.

The fifth aspect may be adapted according to any teaching herein, including but not limited to any one or more of the following options.

Optionally, the data representing the plurality of samples of sets of fabrication process model parameter data values comprises a plurality of sets of fabrication process model parameter data values.

Optionally, the data representing the plurality of samples of sets of fabrication process model parameter data values comprise a set of fabrication process model parameter data values.

Optionally, each fabrication process model parameter data value in the set of fabrication process model parameter data values is an average of a plurality of fabrication process model parameter data values from the distribution of fabrication process model parameter data values.

Optionally, the sampling of the distribution of fabrication process model parameter data values is performed using a quasi-random uniform sampling method.

Optionally, the quasi-random uniform sampling method is a Sobol sequence.

Optionally, the method further comprises determining at least an Nth principal component, wherein the Nth principal component corresponds to a direction in the parameter space which has the Nth largest variance, wherein the maximum value of N corresponds to the number of fabrication process model parameter data values used to define the fabrication process model.

Optionally, the direction of the Nth principal component is orthogonal to the first principal component.

Optionally, the method further comprises sampling along a subset of the N principal components.

Optionally, the number of principle components sampled over is a number that captures at least 90% of the variation in the fabrication process model parameter data values, more preferably 95% of the variation, even more preferably 99% of the variation.

Optionally, the component is an optical photonics component that comprises a defined loss function.

Optionally, the component is fabricated based on a training pattern.

Optionally, the fabrication process model parameter data values are representative of physical parameters of the component.

Optionally, the fabrication process model parameter data values are representative of computational parameters.

Optionally, the computational parameters are parameters defining a kernel.

Optionally, the kernel is a circularly symmetric conical filter kernel.

Optionally, the computational parameters are parameters defining weights in a neural network.

Optionally, the output data is used to define a fabrication process model for use in an inverse design method for optimising the photonic component.

There is also presented, in a sixth aspect, a method for generating a new model parameter. At least one of the steps of the method may be computer implemented.

The method may comprise making a first measurement of a first component of a first design.

The method may comprise making a second measurement of a second component of a first design. Additionally, or alternatively, the second measurement may be for a second design different to the first design.

The method may comprise generating, using a computer processor, a first fabrication process model using the first measurement and the first design.

The method may comprise generating, using a computer processor, a second fabrication process model using the second measurement and the first design.

Each of the first and second fabrication process models comprises a plurality of model parameters. The first fabrication process model comprises a first plurality of values respectively corresponding to the plurality of model parameters. The second fabrication process model comprises a second plurality of values respectively corresponding to the plurality of model parameters.

At least two of the model parameters are common between the first and second fabrication process models. The first plurality of values comprises a first parameter value for a first of the common model parameters. The second plurality of values comprises a second parameter value for the first of the common model parameters. The first parameter value is different to the second parameter value.

The method may comprise generating a new model parameter using at least: A) the first parameter value and the second parameter value; B) a further parameter value associated with the first fabrication process model, for a second common model parameter; C) a further parameter value associated with the second fabrication process model, for the second common model parameter.

The method may further comprise generating a new fabrication process model using the new model parameter.

The method may further comprise using the new fabrication process model to generate a set of data for defining the first design.

The method may comprise using the set of data for making a third component.

The sixth aspect may be adapted according to any teaching herein, including but not limited to any one or more of the following options. Any feature of the sixth aspect and/or any of the options presented underneath for the sixth aspect may be used in any other examples herein, including but not limited to any details regarding: generating a new model parameter; analysing data points; using PCA analysis; sampling new model parameters; uses of a new fabrication process model; reducing the dimensionality of the PCA analysis. Furthermore, the sixth aspect may be adapted by using details of other examples used herein, including but not limited to: details about other fabrication process models; use of EM simulations; types of EM simulations; different types of photonic components; different methods of optimising photonic components; aspects of inverse design; training models for characterisation of a fabrication process; producing an average fabrication process model;

Optionally the first design comprises an intended design.

The first and/or second component may be a photonic component. The first design may be a design for a photonic component. The first and/or second measurement may comprise any one or more of: an image; a scanning electron microscope (SEM) image; an Atomic Force Microscopy measurement; or any other measurement of a physical component described herein. The first and second component may be formed using a fabrication process. The fabrication process may be the same fabrication process.

Optionally, each value in the respective first and second models corresponds to a different model parameter.

Optionally, the first plurality of values comprises a first further parameter value for a second of the common model parameters. Optionally, the second plurality of values comprises a second further parameter value for the second of the common model parameters.

Optionally, the model parameters may comprise any of: a parameter of a kernel; a coefficient of a variable; a physical parameter.

Optionally, any of the fabrication process models may comprise a plurality of variables. Optionally, any of the fabrication process models may comprise a plurality of coefficients wherein each coefficient corresponds to a different variable. Optionally, each variable is a sinusoid of different frequency to the other of the sinusoids. Optionally, each sinusoid corresponds to a different spatial frequency.

Optionally, the new model parameter is generated using Principal Component Analysis (PCA). Optionally, the new model parameter is generated using PCA of two of more, or three or more, model parameters.

Optionally, the new model parameter is defined with respect to the first and second common model parameters. Optionally, the new model parameter is defined with respect to a linear combination of the first and second common model parameters. Optionally, the linear combination comprises: a first coefficient for the first common model parameter; and, a second coefficient for the second common model parameter.

Optionally, the first common model parameter is associated with a first axis of a parameter space; the second common model parameters is associated with a second axis of the parameter space; the new model parameter is associated with a further axis of the parameter space that is different to the first and second axes. Optionally the first axis is orthogonal to the second axis.

Optionally, generating the new model parameter comprises analysing the variance of a plurality of values of a plurality of model parameters.

Optionally, the method uses a plurality of data points in the parameter space. Optionally, each point in the parameter space corresponds to a different measurement of a different component of the first design. Optionally, each point in the parameter space corresponds to a different fabrication process model. Optionally, each data point corresponds to at least two values of two different model parameters for the same fabrication process model.

Optionally, the method comprises making one or more further measurements of one or more further components of the first design. Optionally, each of the further measurements may be used to generate a respective further fabrication process model. Optionally, each of the further fabrication process models may comprise a value for each of the model parameters.

Optionally, the axis of the new model parameter is generated based on a variance in the data points.

Optionally, the axis of the new model parameter is aligned along a direction of the greatest variance in the data points.

Optionally, the method may determine a plurality of new model parameters. Optionally, the axis of at least one of the new model parameters is generated based on a variance in the data points. Optionally, the axis of the at least one of the new model parameters is aligned along a direction of the second greatest variance in the data points.

Optionally, each new model parameter comprises a different axis in the parameter space. These axes may be referred to elsewhere herein as principal components. Optionally, each new axis for each new model parameter may be orthogonal to the other axes for the other model parameters. An example of an axis corresponding to a principal component is reference 1405 in FIG. 15. An example of a first and second model parameters are λ₁ and λ₂ in FIG. 15.

Optionally, a distribution of fabrication process models along the first principal component may be generated. Optionally, samples of one or more new fabrication process models may be generated using a sampling method, wherein each new fabrication process model has associated with it a set of new model parameter values for a plurality of new model parameters.

Optionally the method takes a plurality of samples along the first principal component. Optionally, samples may also be generated along each further new model parameter axes. Optionally, the sampling method may be a low-discrepancy quasi-random sampling method which uniformly samples the parameters across the sampling space. Optionally the low-discrepancy quasi-random sampling method which uniformly samples the parameters across the sampling space may be a Sobolsequence.

Optionally the plurality of new model parameters comprises a number of new model parameters.

Optionally samples may be taken along a number of principal components, wherein the number of principal components is less than the number of new model parameters. An example of a new model parameter may be P₁=A₁*λ₁+A₂*λ₂, wherein λ₁ and λ₂ are the original model parameters, and A₁ and A₂ are coefficients for those model parameters.

Optionally, an average fabrication process model may be generated based on an average of the new model parameters.

Optionally, a set of data for defining a new design may be generated based on the average fabrication process model or the samples of the fabrication process models.

Optionally, the set of data for defining the new design is used to generate a component data model. The data model may be a GDS file. Optionally the model may represent a photonic component. Optionally, the method may comprise running an Electromagnetic simulation on the component data model.

Optionally, the first and second designs may be test structures. Optionally, the first and second designs may each comprise a pattern of features. The pattern may comprise a noise distribution. The first design and second design may comprise a different pattern. The pattern may be a 2D pattern. The pattern may be for a plan view of the respective component. The pattern may comprise rectilinear features. The method may use the new fabrication process model for outputting data for making a photonic component.

### BRIEF LIST OF FIGURES

Embodiments of the present invention will now be described in detail with reference to the accompanying drawings, in which:

FIG. 1a is a schematic example of a computer system for outputting data for defining a component for guiding electromagnetic waves;

FIG. 1b shows an example of a prior art method of inverse design;

FIG. 2 shows an example of a conceptual model of an optical power splitter;

FIG. 3 shows a design concept for a photonics optical power splitter;

FIG. 4 shows a more detailed view of the dispersive region of an optical power splitter;

FIG. 5 shows a functional block diagram of the components of a photonic device simulator;

FIG. 6 shows a functional block diagram of the elements of a fabrication transform tool;

FIG. 7 shows an illustration of an example fabrication process model training pattern;

FIG. 8 shows more detailed examples of training patterns;

FIG. 9 shows a flow diagram of a method to generate a fabrication process model;

FIG. 10 shows an illustration of the configuration of a simulation environment;

FIG. 11 shows a flow diagram of a method to optimise the physical parameters of a photonic device for a specific fabrication process, based on an average fabrication model of a specific fabrication process;

FIG. 12 shows a flow diagram of a method to optimise the physical parameters of a photonic device for a specific fabrication process, based on the sampling of a fabrication model of a specific fabrication process;

FIG. 13 shows the process to determine gradients of a loss metric with respect to the fabrication model parameters by utilising the gradients of the loss metric with respect to the structural parameters of the photonics device, obtained via the adjoint method;

FIG. 14 shows a flow diagram of a method to optimise the physical parameters of a photonic device for a specific fabrication process, based on an average fabrication model of a specific fabrication process including the sensitivity of the device to the fabrication model parameters.

FIG. 15 shows a 2-dimensional representation of sampling sets of measured fabrication model parameters performed using principal component analysis (PCA).

### DETAILED DESCRIPTION

The present application is directed to computer systems, computer implemented methods and methods of forming one or more components for guiding electromagnetic, EM, waves. Underneath is a generic example of the computer system and associated methods. Other examples of computer systems and methods are also presented herein. It is to be understood that features and configuration of the other examples may be used with this generic example. It is also to be understood that any of the optional features and configurations contained in other parts of the application, including but not limited to the as filed claims and the as-filed summary section may be combined with this generic example.

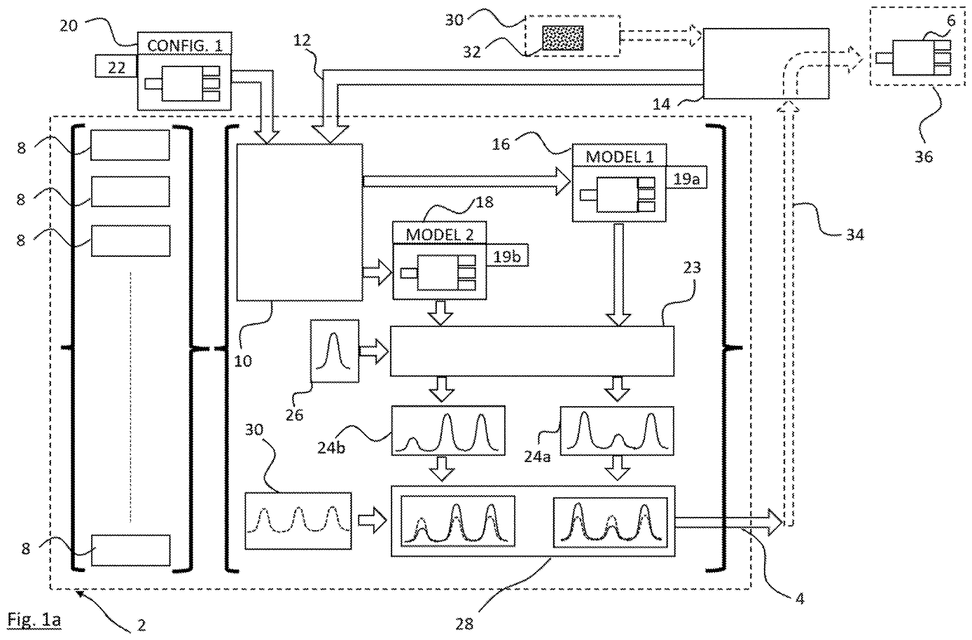

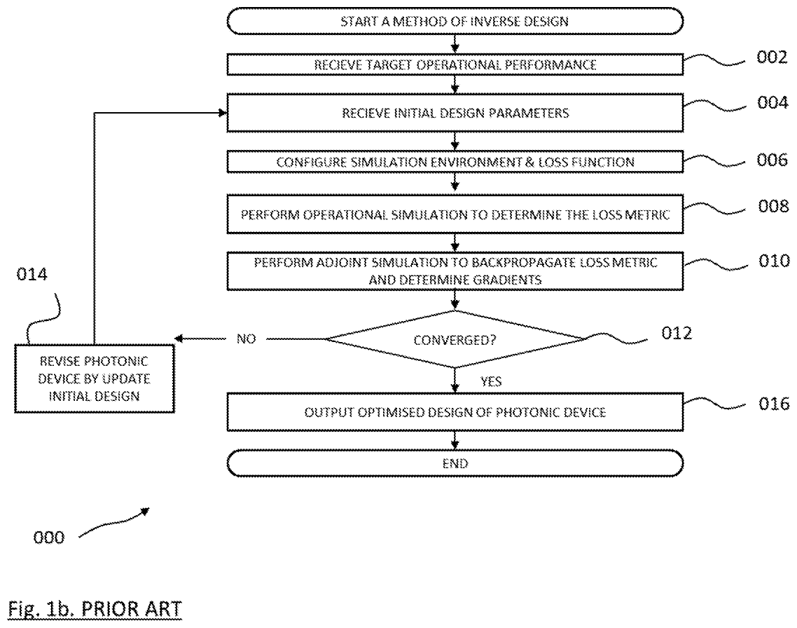

FIG. 1 shows a generic example of a computer system (2) for outputting data (4) for defining a component (6). The component is for guiding electromagnetic waves. The computer system (2) comprises one or more modules (8). The representation in FIG. 1a is meant for understanding purposes only, wherein the multiple modules (8) vertically listed in the vertically extended brackets in the left-hand portion of the computer system (2) may perform the functions of the pictorial process in the vertically extended brackets in the left-hand portion of the computer system (2), and optionally other processes too. The block arrows in the figure represent either next steps or data flows.

The modules are configured to generate a fabrication process model (10) using data (12) measured from one or more outputs of a physical fabrication process (14) suitable for forming the component (6).

The modules are configured to generate at least a first model (16, MODEL 1) of the component (6) and a second model (18, MODEL 2) of the component (6) by applying the fabrication process model (10) to an initial configuration (20, CONFIG. 1) of the component (6).

The initial configuration (20) of the component (6) is associated with one or more physical parameter data values (22). The first (16) and second (18) models of the component (6) each comprise one or more data values (19a, 19b) associated with the one or more physical parameter data values (22) of the initial configuration (20). At least one of the said data values (19a) of the first model (16) of the component is: a) associated at least one of the physical parameter data values (22); and, b) different to the corresponding data value (19b), of the same physical parameter, of the second model (18) of the component;

The modules are configured to determine (23), for each of the first and second models of the component, a computer-modelled electromagnetic field output (24a, 24b) of the respective model for a given electromagnetic field input (26) to the respective model of the component (6);

The modules are configured to compare (28), for each of the first and second models of the component, the respective electromagnetic field output (24a, 24b) to a common pre-defined electromagnetic field output (30).

The modules are configured to output, based on the comparisons, data (4) for defining the component (6); the output data associated with the physical parameters (22) of the initial configuration (20) of the component.

In some examples, only a single model may be generated. In some examples one or more computational parameters, such as kernels, are associated with the fabrication process model. Another term used herein for the fabrication process model is ‘fabrication transform tool’. A computational parameter may be varied between different versions of the model of the component generated by the system, for example the first model may be generated using a first version of the parameter whilst a second version of the parameter (which has one or more data values different to the first version), is used to generate the second model. Each version of the computational parameter may affect one or more, preferably multiple, physical parameter values of the models that are subsequently simulated. For example, a first version of the computational parameter kernel provides a sidewall surface roughness of +\−0.1 nm and a minimum core waveguide feature of 0.3 nm whilst a second version of the computational parameter kernel provides a sidewall surface roughness of +\−0.2 nm and a minimum core waveguide feature of 0.4 nm. Having a single computational parameter that takes different versions to affect multiple degree of physical parameter changes is efficient in computational processing power/time compared to changing each physical value. An average kernel may be used and/or a kernel may utilise one or more averaged data values forming the kernel.

Prior art modelling methods have taken theoretical ranges of component parameter variations that may theoretically occur in different fabrication runs. A plurality of such parameter range variations may be taken into account in electromagnetic modelling of the component. For example, a prior art method may identify that waveguide core layer thickness and minimum lithographically resolvable distance between different core layer features are key variables that need modelling. For discussion purposes here, the minimum lithographically resolvable feature distance is the minimum distance that two core layer features can be apart before the process forms them into a single feature with no separation despite the intention for there to be a separation (e.g., a separation occupied by a cladding material). With these two features, the prior art would establish range variation for each, for example minimum lithographic distance may range from 0-50 nm whilst thickness variations may range from −100 nm-+100 nm of the nominal design thickness. The prior art method would then choose an appropriate step increment between the ends of the ranges. The prior art method would then, for example, for each increment of core layer thickness, sweep through all the minimum lithographic distances. Each instance of the component being formed according to that particular set of fabrication variation would be EM modelled. This in turn would create a matrix of EM modelling outcomes. If, for example, the target component to be modelled was a 2×2 integrated optical coupler then the matrix may detail each of the output coupling ratios for each one of the fabrication variations. This process is time consuming as many EM modelling runs need to be made—to the size of the matrix, which may have in excess of 30 dimensions, for example.

Unlike the prior art, the present system and method generate a fabrication process model based on measurements of an output of the fabrication process. This allows for process variations of the component to be generated (for EM modelling) taking into account the real variations of the actual process that may be used to actually fabricate the component. As such, worthwhile and meaningful values and end ranges may be used to make sure the range of variation is realistic, and the component design reflects what actually may be made. Furthermore, prior art methods assume no fabrication variable coupling. It may be, for example, that at certain core thicknesses, above a threshold value, the minimum lithographic distance increases. Thus, a design created by the prior art with a core thickness above that thickness threshold and a minimum lithographic distance below the associated threshold would be unnecessary and redundant because the fabrication process could not actually produce that variation of component. The prior art is therefore prone to modelling unnecessary variations of components. Again, the system and method presented herein may solve this problem by generating a fabrication process model based on measurements of outputs of the actual process, which, in turn would take into account this process variable coupling. The system and method herein therefore may reduce the number of simulations required to determine the optimal parameters for manufacturing a robust component which achieves a specific figure of merit, e.g. for a Y-branch optical power splitter, the figure of merit may be a specific ratio of output powers from the two output regions, e.g. 30:70. This reduction in the number of simulations may lead to a faster, more computationally efficient optimisation of a component which is robust to the fabrication process.

Turning back to FIG. 1a, the system shown is a generic example presented in a pictorial format that is not intended to represent and detailed function, but more for the conceptual understanding of the reader. It is noted that the initial configuration 20 and/or the parameter(s) 22 of the component may be presented to the system 2 by an external source such as a human or another computer system, or may be generated by a module 8 the system 2 itself. The dashed arrows in FIG. 1a such as the arrows from test pattern generation 30 and arrow 34, and the dashed boxes outside the computer system 2 are intended to show optional steps in a method or an apparatus.

As discussed above, the system may output data for defining the component. The generation of this data may be made using fewer computer processing steps than the prior art. As an option, the output data 4 may be used to fabricate the component 6 using the fabrication process 14 used to generate data 12 for generating the fabrication model 10, or another fabrication process. The ‘fabrication process’ here may refer to either the particular set of equipment (i.e., a process defined by the actual equipment pieces used) for fabrication; or a process that may be executed using types of equipment run in a particular way. For example, the fabrication process may involve the use of a particular individual flame hydrolysis (FHD) machine and the fabrication process model is developed particularly for that machine and how it has been set up to run. Additionally, or alternatively, the fabrication process model may be generated for a particular class of equipment or equipment set-ups. In other words, the fabrication process model may be generated to represent the fabrication process of any particular set of equipment of a particular type; for the FHD example above, the Fabrication process model may be suitable for any particular equipment setup of the same FHD machine setup. Hence the fabrication process model may be particular to a unique set of equipment or a plurality of sets of the same equipment that share common fabrication attributes.

The fabrication process may be any suitable component fabrication processes for forming samples such as EM components such as optical components and test structures, for example, for training the fabrication model upon. Fabrication processes may include any of, but not limited to: substrate/wafer formation; substrate/wafer preparation including any of cleaning, etching and surface planarization; layer formation upon the substrate and other layers including growth (such as thermal oxidation) and deposition of material; component patterning and lithographic definition, including any of electron-beam patterning or etching, dry and wet etching; chip formation including cleaving; device testing and measurement. Measuring real fabrication samples from the process whether they be the component or test samples for use with generating the fabrication process model, may include any imaging processes (be it using EM radiation or particles such as a scanning electron microscope (SEM)) and or any physical interrogation processes whereby an interrogating element contacts the sample, for example a probe that feeds back contours of the cross section.

Examples of computer system components are detailed elsewhere herein and may be used with any of the examples present underneath. In brief the computer system typically comprises: one or more electronic processors for operating on data; and one or more memory devices communicatively coupled to the processors for storing, retrieving data wherein the data may be any of instructions for performing the methods described herein and/or data resulting from the execution, by the processor, of those method steps. A data output device for outputting the data may include any of, but not limited to: an interface for transmitting data to an external memory, a wired or wireless communications interface to an external entity such as another computer system.

The component is preferably an optical component. The component is preferably a waveguide. The waveguide may be an optical fibre or an integrated optic component, a combination of both or another waveguiding optical component. The component may comprise at least one input for receiving EM radiation and at least one output for outputting EM radiation. The optical component may be operative to transform a property of the EM field to give rise to the output field. The property of the EM field may be spatial mode profile along or transverse to the direction of propagation, a temporal profile, polarisation, wavelength. Examples of components include but are not limited to: tapers, mode matching tapers, couplers, splitters, mode transformers, polarisation splitters, polarisation combiners, polarisation rotators, active waveguides, passive waveguides, gratings, arrayed waveguide gratings, Bragg gratings, interferometers.

Any of the modules may be software modules or hardware module. A different module may be used to perform the action of each of the listed items above. Furthermore, a different module may be used to perform the actions of any of the options listed underneath and elsewhere herein. Alternatively, any one module may perform one or more of the actions listed above.

The first model and second model correspond to different expected manufacturing variations of the component. The first and second model may be generated from data associated with an input model of the component.

The input model of the component is associated with a plurality of physical parameters. By applying different transformations to the input model, a plurality of output models may be generated. These output models may comprise the first and second model. Alternatively, the first and second model may be generated from the said output models. For example, the input model may be a desired model of the component. The output models may represent different possible variations of the desired component. The different possible variations may arise from different fabrication (hence manufacturing) process variations. The input and output models of this process may be of a particular type and take a particular format. The format of the output models, in some circumstances, may be used as the first and second model, or the first and second model may be generated by performing data processing on the output models. Such data processing may include sampling the output models, for example the first and second models may represent discrete sampled values of the output models. The first model and second model are each associated with a respectively different (preferably single) output model.

The above said transformation to generate the first model is different to the transformation to generate the second model. The transformations may be determined from one or more rules associated with manufacturing variations.

The physical parameter may be any numerical or other measurable factor forming one of a set that defines the component or sets the conditions of its operation. Physical parameters may be material related values at one or more portions of the component. Material properties may be any of refractive index either real or imaginary or both; electric permeability, electric permittivity. Physical parameters may be dimension-related, for example a value defining the extent of a particular material of the component in one or more directions.

The physical parameters may comprise any of, but not limited to: waveguide widths; waveguide heights, waveguide lengths; number of input waveguides; number of output waveguides; component size in a direction parallel to the plane of the substrate; refractive index of core material; refractive index of cladding material; length/with/depth of EM coupling or splitting regions or any other component region intended to transform one or more input EM modes to one or more output EM modes.

FIG. 1b shows a flow diagram of the prior art method of inverse design 000, which is a method to optimise the physical parameters of a photonic device.

The method of inverse design 000 proceeds from a start block to block 002, where the target operation performance of a photonic device is received.

Blocks 002 then proceeds to block 004 where the initial design parameters, described by one or more physical parameters which define the photonic device, are received.

Block 004 proceeds to block 006 which configures the simulation environment based on the initial design of the photonic device, including the excitation input regions and output regions and input excitation source values. The physical parameters which describe the photonic device are mapped to structural parameters in the simulated environment. The loss function is also defined using the target operational performance of the photonic device. The loss function can be defined in any way such that a loss metric can be determined to quantify the performance of the simulated physical device. The loss function may combine the target operational performance with other functions which determine metrics which might relate to other elements, such as fabricability of the device as determined by a minimum feature size constraint. In general, any number of penalisation terms can be included in the loss function which act to influence the path of an optimisation procedure.

From block 006, method 000 proceeds to block 008 which performs the operational simulation of the photonic device described in the simulation environment, such that after termination of the simulation, the loss metric can be determined using the output electromagnetic field values, structural parameters, and the loss function.

From block 080, method 000 proceeds to block 010 which uses the field values from the operational simulation and the loss metric to define an adjoint simulation. The adjoint simulation is performed which backpropagates the loss metric through the simulation, to determine gradients of the structural parameters which can be subsequently backpropagated to determine gradients of the physical parameters which describe the photonic device.

From block 010, method 000 proceeds to decision block 012 where a determination is made on whether the loss metric has substantially converged such that the operational performance and target operational performance are within a threshold range, or the loss metric which potentially includes a plurality of additional constraints is below a threshold value.

If the decision is NO, the method 000 proceeds to block 014 which revises the initial design of the photonic device. The revised physical parameters may be determined independently of the calculated gradients, or through utilisation of the gradients determined in block 010. In some cases, the revised description may be generated though utilising an optimisation scheme together with a cycle of operational and adjoint simulations and a gradient-based optimisation algorithm, which could be gradient descent. In other cases, another type of gradient or non-gradient-based optimisation scheme may be used to generate a revised set of physical parameters. In general, iterative cycles of operational simulation, adjoint simulation and revision of the physical parameters may be used until the convergence of loss metric is substantial such that the decision at block 012 exits under the YES condition.

If the decision at block 012 is a YES, method 000 proceeds to block 1016 which outputs the optimised physical parameters corresponding to the design of the photonic device before termination of the method.

The applicants herein disclose methods of improving the inverse design method 000 by inclusion of a fabrication model to account for real process variation, such that robust photonic device design is performed in a faster, more efficient, and less computationally expensive manner. It is also possible to determine the robustness of each fabrication design using methods disclosed herein.

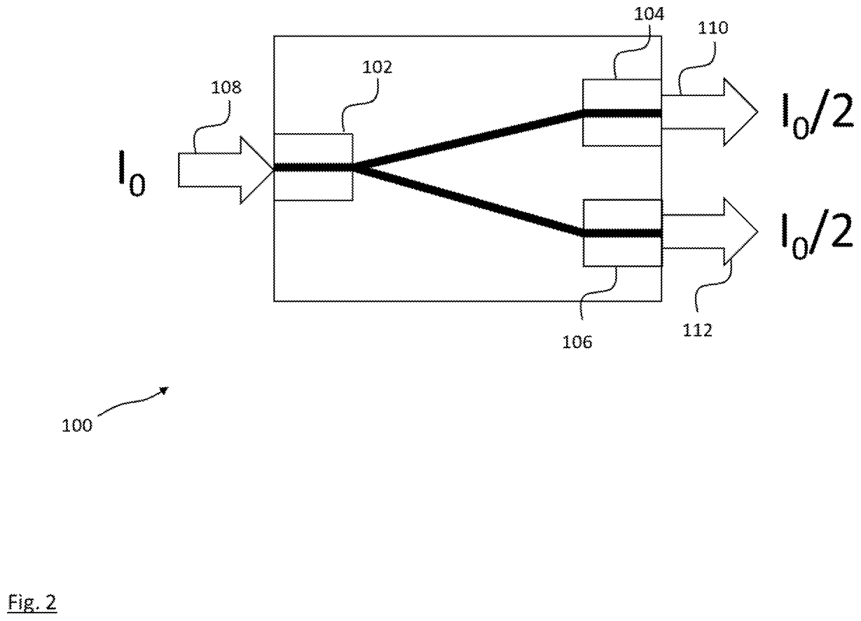

FIG. 2 shows a drawing of a conceptual model of a component that may be produced via a real fabrication process. The nomenclature discussed underneath may be used in other examples herein.

In FIG. 2, there is shown an example of an optical power splitter 100 which includes an input region 102 and two output regions 104 and 106. Optical power splitter 100 is configured to receive an optical signal 108 via input region 102 (e.g., a waveguide) to spatially separate the optical power received from optical signal 108 and respectively guide each of the two distinct optical powers to a corresponding output region 104 and 106 (e.g., a plurality of waveguides). Two distinct optical powers at output regions 104 and 106 then provide an optical power to output signal 110 and 112, respectively. In the example shown in FIG. 2, optical power splitter 100 takes an input optical signal 108 with optical power I₀ and evenly splits the power into two distinct output regions 104 and 106, each having an optical power I₀/2. In other examples, the photonic optical power splitter may split the input optical power into any ratio a:b, where a is the faction of the optical power guided to output region 104, and b is the fraction of optical power guided to output region 106, such that the sum of a and b is unity. In other examples, there may be a plurality of distinct output regions to form a 1×N optical power splitter. Optical input signal 108 may contain a plurality of distinct wavelengths such that I₀(λ) and optical output signals 110 and 112 are then a(λ)·I₀(λ) and b(λ)·I₀(λ). For a given design of the photonic optical power splitter, which is not symmetric, the fraction of the optical power guided to the output regions 104 and 106 depends on the wavelength. For a design optimised to work in the telecommunications C-band, 1530 nm-1565 nm, a typical operating wavelength of a photonic optical power splitter would be 1550 nm. Optimisation of the design of the photonic optical power splitter may also include a target metric for the output ratio of the optical power over a given wavelength bandwidth. A typical operating bandwidth for a design optimised for 1550 nm would be 10 nm. Another bandwidth would be the span of the C-band. An excellent bandwidth would be 1500 nm-1600 nm.

It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example. Such features may include but are not limited to any one or more of: details about the type of device, for example the optimisation can be applied to any general N input M output device, that can be on any SOI or integrated photonics process.

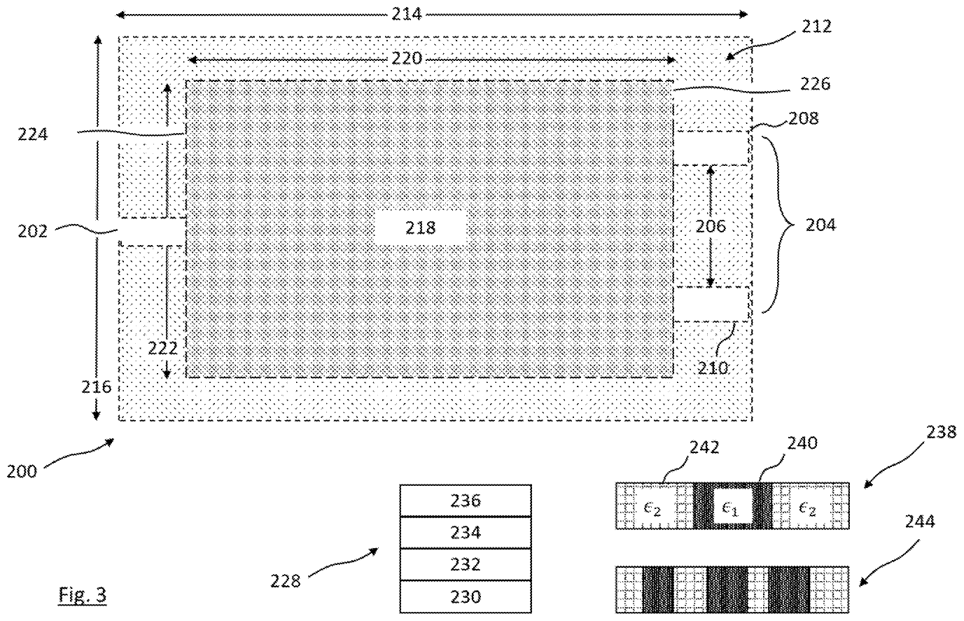

FIG. 3 shows a design concept for a photonics optical power splitter. The design may be modelled by the computer system (2).

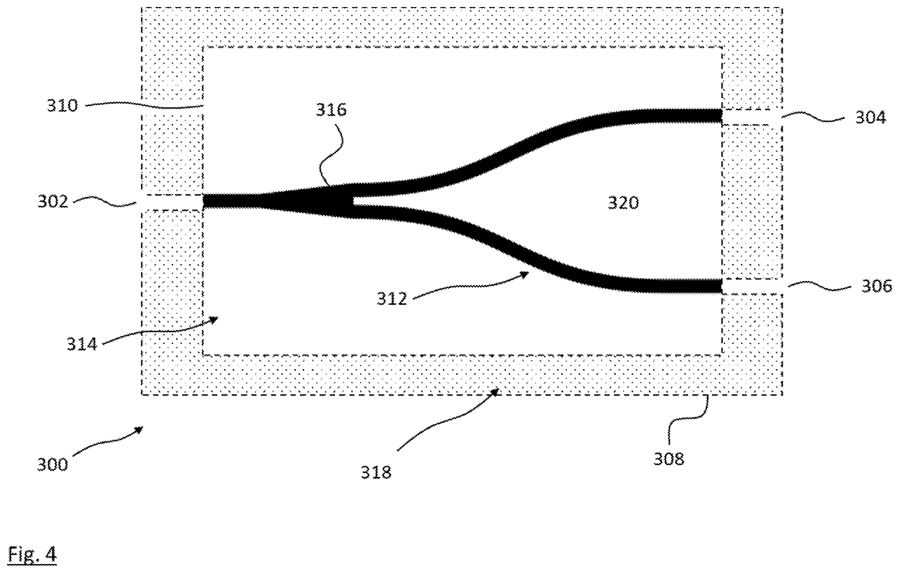

In FIG. 3 there is shown an example illustration of a different view of a photonic optical power splitter. Optical power splitter 200 is one implementation of optical power splitter 100. The discussion now may be directed towards PICs capable of spatially separating and distributing the optical power of a single input signal to two or more distinct output signals. FIG. 3 shows a cross-sectional view of optical power splitter 200 along the lateral plane within an active layer defined by a width 216 and a length 214 of the optical power splitter 200. However, components may not be necessarily defined by width and height, they may be other shapes described with other geometrical parameters. For example, the radius may be used for a circular component, or a major and minor axis (or loci) may be used for an elliptical component, or more generally a function defining the shape of an irregular component which may be curvilinear. For example, the geometry may be defined by a level-set function, or another function entirely. The shape of the component may be a composite shape, comprising two rectangular regions adjacent to one another, each with their own respective width and height. In another example, the shape of the component may be comprised of a rectangular region that is adjacent to a semi-circle, where the rectangular region may be defined by its width and height and the semi-circle may be defined by its radius. As illustrated, optical power splitter 200 includes an input region 202 (e.g., compared to input region 102 in FIG. 2), a plurality of output regions 204 which in this example contain output regions 208 and 210 (e.g., compared to output regions 104 and 106, respectively) and a dispersive region optically disposed between the input region 202 and the output region 204. The input region 202 and the plurality of output regions 204 (e.g., output region 208 and 210) may each be waveguides (e.g., slab waveguide, strip waveguide, slot waveguide, rib waveguide, or similar) capable of propagating light along the path of the waveguide. The dispersive region 218 includes a first material and a second material which may be homogeneously or inhomogeneously dispersed to form a plurality of interfaces between the first material and the second material. When the material is homogeneously disposed, it is understood that there are uniform sections of the first material and the second material over an appreciable length scale, such as a waveguide, where the material interfaces form regular boundaries, typically with a rectilinear shape. When the material is said to be inhomogeneously disposed, it is understood that the first material and the second material may be randomly located over a given length scale, such that the material interfaces form irregular boundaries, typically curvilinear in shape. Each interface corresponds to a change in the refractive index of the dispersive region 218. The dispersive region 218 of dimension 220 in length and 222 in width provides the structure to optically split the power from input region 202 to the plurality of output regions 204. The shape and arrangement of the first and second material that is homogeneously or inhomogeneously interspersed is dispersive region 218, shown more clearly in the example in FIG. 4, is surrounded in part by a periphery boundary region 212 which is homogeneous in composition and includes the second material. The dispersive region 218 has a first side 224 and a second side 226 each with an interface with the inner boundary of the periphery region 212. The first side 224 and the second side 226 correspond to opposing sides of the dispersive region 218. Input region 202 is disposed adjacent to the first side 224 of the dispersive region and the plurality of output regions 204 are disposed adjacent to the second side 226. In the example show in FIG. 3, input region 202 and the plurality of output regions 204 are parallel to each other, however, they can also be disposed at any arbitrary location and rotation which connects to any side of the dispersive region 218. The example here shows a separation 206 between the output region 208 and 210 in the plurality of output region 204. In some cases, the plurality of output regions has a common spacing. In other cases, there can be a distinct spacing between individual output regions of the plurality of output regions 204. The plurality of interfaces of the first material and the second material in dispersive region 218 form a material interface pattern (shown in more detail in FIG. 4) along the cross-sectional area of the dispersive region 218 which cause the dispersive region 218 to optically split the power and route the power to output regions 208 and 210 when input region 202 receives an optical signal.

It is noted that the first and second material of dispersive region 218 can be arranged and shaped such that the material interface pattern is recognisable to one skilled in the area as being a design obtainable with an inverse design process, which will be discussed in greater detail later. In some cases, the inverse design process may include an iterative gradient-based optimisation of a design based on a loss function, which incorporates details of the target operational performance of the design in addition to details which relate to the ability to fabricate such a design and the robustness/repeatability of fabrication of a design, where the loss function is reduced or otherwise via iterative gradient-based optimisation to generate the design. It is also noted that other optimisation techniques may be used, instead of or in combination with, gradient-based optimisation. This enables optimisation of a design with an exceptionally large number of design parameters to achieve operational function and performance that would not be possible with a conventional design technique.

For example, in one case, dispersive region 218 is structured to optically split the power of an optical signal within a pre-determined area of 17 μm×9.5 μm (as defined by length 220 and width 222) when input region 202 receives an optical signal. In this example the optical power splitting can be a ratio of 0.7:0.3. In other cases, the size of the pre-determined area may be different, and the ratio of the optical power splitting may also be different. In such cases it is noted that the shape and arrangement of the first material and the second material in the dispersive region 218 will be different.

FIG. 3 also shows a vertical schematic 228 of the stack of various layers that are included in the illustrated example of the optical power splitter 200. It is noted that this schematic is not intended to be exhaustive and there may be similar features or elements in other cases of a layer stack which describe materials comprising a PIC. In the illustrated example, optical power splitter 200 includes substrate layer 230, dielectric layer 232, active layer 234 (e.g., as shown in the cross-sectional illustration of optical power splitter 200) and cladding layer 236. In some cases, optical power splitter 200 may be in part or otherwise a PIC or silicon photonic device compatible with a conventional CMOS fabrication technique (e.g., lithographic techniques such as photolithography, electron-beam lithography or similar, sputtering, thermal evaporation, physical and chemical vapor deposition, and other typical fabrication techniques common to conventional semiconductor processing). A semiconductor wafer can be provided which may be a silicon on insulator (SOI) wafer, which includes a silicon substrate layer which corresponds to substrate layer 230, a silicon dioxide dielectric layer which corresponds to dielectric layer 232, a silicon layer which corresponds to active layer 234 (e.g., intrinsic, doped or otherwise) and an oxide layer which corresponds to cladding layer 236 (e.g., intrinsic, grown or otherwise). The silicon in the active layer 234 may be selectively etched by using lithography to pattern a SOI wafer. The wafer may first be coated with a photoresist mask, or other hard mask, such that after the pattern is transferred to the SOI wafer by the lithography process, an etching process (e.g., dry etch) can be used to selectively etch portions of the silicon. The silicon can be etched all the way down to the dielectric layer 232 or it can be partially etched to leave any remaining thickness of silicon in the active layer 234. The void left by etching away portions of the silicon can be filled in some cases with silicon dioxide which is further encapsulated with silicon dioxide to form a cladding layer 236. In some cases, there can be multiple distinct etch depths. In some cases, the silicon can be 220 nm thick and a full etch would then be 220 nm, a typical partial etch depth might be 70 nm. The process to fill the voids with silicon dioxide and application of more silicon dioxide to form a cladding layer may be a several stage process which involves intermediate steps to planarize the surface. A more detailed schematic 238 of the active layer 234 shows a case where a first material 240 with a refractive index ε₁ and a second material 242 with refractive index ε₂ are interspersed quite homogeneously. Homogeneous regions of the first material 240 and the second material 242 may form waveguides or sections of waveguide (e.g., input region 202 and the plurality of output regions 204). A more detailed schematic 244 of the active layer shows a case where a first material 240 with a refractive index ε₁ and a second material 242 with refractive index ε₂ are interspersed quite inhomogeneously. Inhomogeneous regions of the first material 240 and the second material 242 which form a plurality of interfaces in the lateral cross-section can collectively form a dispersive region which may, with a given arrangement and shape, form a dispersive region which can provide functionality which, for example, performs an optical power splitting. It is noted that dispersive regions that are either largely homogeneous or largely inhomogeneous, or any intermediate combination, can be the result of design optimised to perform a function of an integrated photonic device. In the example illustrated in FIG. 3, the functionality of an integrated photonic device is to perform an optical power splitting.

It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example. Such features may include but are not limited to any one or more of: details about the size of the device, number of inputs/outputs, the materials in the vertical stack, the refractive indices, target operation of device, etch depths, process techniques, etching techniques, cladding or no cladding.

In FIG. 4 there is shown another, more detailed, cross-sectional view of the dispersive region of optical power splitter 300. Optical power splitter 300 is one possible implementation of optical power splitter 100, illustrated in FIG. 2, and optical power splitter 200 illustrated in FIG. 3.

As shown in the example of FIG. 4, optical power splitter 300 includes an input region 302 and a plurality of output regions 304 and 306. Dispersive region 320 is surround by a periphery region 318 that has an inner boundary 310 and outer boundary 308. The first material 312 (black coloured regions in dispersive region 320) and the second material 314 (white coloured regions in dispersive region 320) of the optical power splitter 300 are homogeneously dispersed to create a plurality of interfaces 316 that collectively form a material interface pattern. Moreover, an inverse design process that uses iterative gradient-based optimisation techniques combined with first principles simulations to generate a design that is like dispersive region 320 within a proportional manner, such that optical power splitter 300 provides the desired functionality. In the illustrated examples, dispersive region 320 is structured to optically split power with a ratio 0.7:0.3, into output regions 304 and 306, respectively.

It is noted that in other examples, the first material 312 and the second material 314 may be significantly more inhomogeneously disposed, possibly with regions of the first material 312 forming islands in close, or not close, proximity to larger regions of the first material 312. It is appreciated that the general structure of the first material 312 and the second material 314 will largely depend on the loss function used in the iterative gradient-based optimisation procedure, in addition to, but not in all cases, the initial conditions of the parameters used for the iterative gradient-based optimisation.

In some cases, the inverse design process includes a plurality of penalty functions which enforce fabricability constraints, such that a resulting design can be fabricated within the desired design rules which can enforce features such as, but not limited to, minimum feature size. In the illustrated examples, optical power splitter 300 is shaped to enforce a minimum features size within dispersive region 320 such that the interfaces 316 of the first material 312 and the second material 314 does not have a feature less than the desired magnitude. In one example this could be 200 nm but can in principle can be any desired magnitude. In some cases, other penalty functions may be included in the inverse design process which enforce desired effects, which can be related to the fabricability or other effects, such as a particular structure of the confinement of the electromagnetic energy within the first material 312 or second material 314.

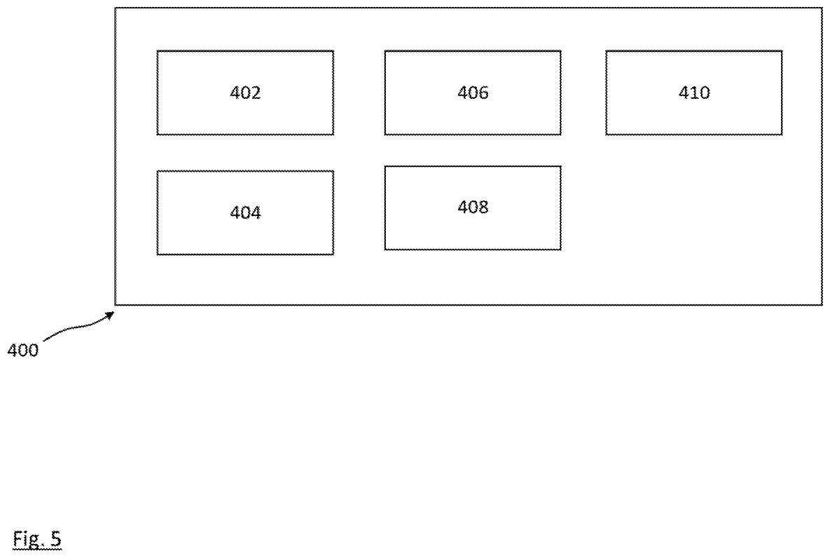

In FIG. 5 there is shown an example of a functional block diagram of the components of a photonic device simulator 400. A photonic device simulator 400 can be utilised to optimise structural parameters of a photonic device (e.g., optical power splitter 300 in FIG. 4, optical power splitter 200 in FIG. 3 etc.) The physical parameters of a photonic device may be optimised via simulations (e.g., operational and adjoint simulations) that utilise the finite-difference time-domain (FDTD) method to model the field response (e.g., electric, and magnetic fields) within a photonic device. Other methods may be used such as mode-matching method, Finite element methods, beam propagation methods or eigenmode expansion. The operational simulation 402 provides instructions for performing electromagnetic simulation of the photonic device in response to an excitation source with a simulated environment. Moreover, the operation simulation determines a field response in response to an excitation source in a simulation environment which determines the operation of the photonic device within the simulated environment. The operation of the photonic device in the simulated environment may be used to determine a performance metric of the physical device (e.g., from an initial description of the photonic device where the physical parameters can be mapped to structural parameters which describe the photonic device within the simulation environment with a plurality of voxels). The structural parameters may correspond to the specific design, material composition, dimensions, or other feature of the physical device.

Fabrication transform tool 406 provides instructions to perform a fabrication simulation of the initial structural parameters, such that the output structural parameters are correspondent to the as fabricated physical device within the simulated environment. In some cases, the fabrication transform tool 406 may provide instructions for a generic fabrication simulation of the structural parameters. In other cases, the fabrication transform tool 406 may provide a specific set of instructions to perform a fabrication simulation of the structural parameters, where the specific set of instructions correspond to a specific fabrication process. Moreover, there can be a plurality of specific instructions for how to perform a fabrication simulation of the structural parameters, for a specific fabrication process. Loss function calculation 410 computes a loss metric determined via a loss function that incorporates a performance loss function, which determines a performance metric, and a plurality of penalty functions, which each determine a penalty loss for the penalty function. Adjoint simulation 404 is utilised in combination with operational simulation 402 to perform an adjoint simulation of the photonic device to backpropagate the loss metric through the simulated environment. The backpropagation of the loss metric via the loss function is used to determine how changes of the structural parameters of the photonic device influence the loss metric. Optimisation engine 408 is utilised to update structural parameters of the photonic device to reduce the loss metric, thus generating a new description of the photonic device.

It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example. Such features may include but are not limited to any one or more of:
i) The simulation can be performed by any method that determines one or more characteristics of the electromagnetic field in response to an excitation source.
ii) The photonic device simulator may be part of a computer system which can perform this calculation.
iii) The computer system can be distributed such that steps may be performed in parallel where appropriate.
iv) The fabrication transform tool does not always have to be used in the optimisation process.
v) The adjoint simulation does not have to be utilised in cases of gradient-free optimisation.

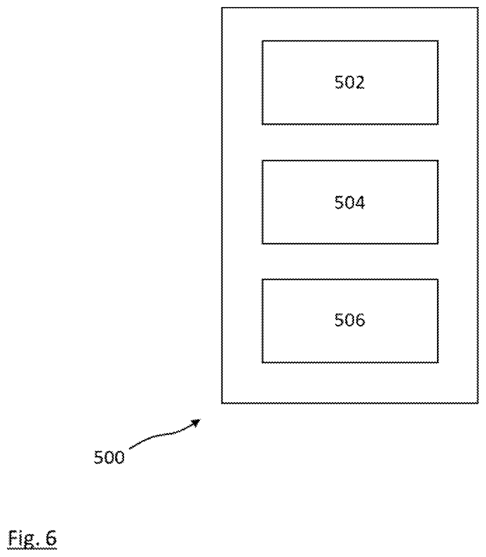

In FIG. 6 there is shown a functional block diagram of the elements of the fabrication transform tool 500 which can be the fabrication transform tool 406. Fabrication transform tool 500 provides instructions on how to perform a fabrication simulation of the structural parameters of a photonic device in a simulation environment. A set of instructions are provided via a fabrication model 506, which has been trained using fabrication process training data 504 that may have in part been acquired using a set of training patterns 502. Fabrication process training data 504 can include a plurality of distinct sources of training data, all of which relate to a specific fabrication process, e.g., a particular SOI process at a certain semiconductor processing foundry. Examples of fabrication process training data might include data such as, but not limited to, wafer height variation, fabrication linewidth variation, scanning-electron microscope (SEM) images, focused ion beam SEM images, atomic-force microscope (AFM) images, optical response data of physical devices, chemical resist etching profiles, light intensity distribution profiles of the lithography optical system and line-edge roughness (LER) statistical data. This is not an exhaustive list, and it is appreciated that any related measurement that can be used to discriminate a feature of a semiconductor fabrication process may form the basis of one of a distinct set of the plurality of fabrication process training data.

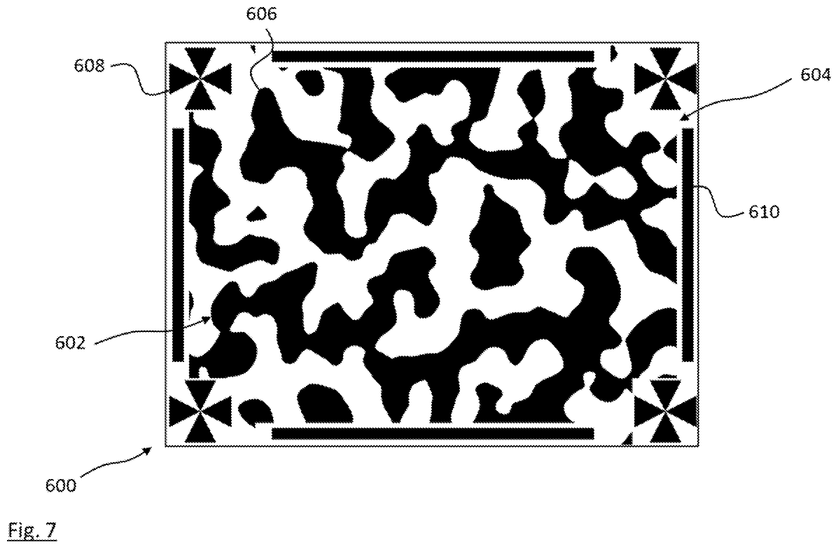

Fabrication process training data 504 may include sets of training data which have been acquired using training patterns 502. Using training patterns to acquire the training data may be advantageous as they may be non-conventional or odd patterns, such as comprising “blobs”, as opposed to only the typical rectilinear structures which may be found in more conventional components. Training patterns 502, shown in more detail in FIG. 7, are designs which are in the first case used as part of a characterisation a semiconductor fabrication process, discussed later. Such designs are fabricated on a target fabrication process where subsequently data can be acquired using the fabricated designs. In some cases, this can be SEM images of the fabricated training patterns 502. Fabrication process training data 504 may include other sets of process characterisation data, such as those acquired using standard process characterisation structures, e.g., photolithography feature size discrimination patterns. Fabrication process training data 504 may additionally include data from optical characterisation of photonic devices e.g., spectral response of a Mach-Zehnder interferometer with a relative delay length of 100 um, or spectral response of a micro-ring resonator with a ring radius of 20 um.

Fabrication process training data 504 is used to train a model of the fabrication process 506, which can then provide a set of instructions to perform a simulation of the fabrication of structural parameters of a photonic device in a simulation environment. In general, the model of the fabrication process is generated by determining a transformation or generalised function, which can be trainable, that takes input data which can be used to describe a photonic device in a simulation environment, and outputs data which can be used to define a photonic device in a simulation environment. The transformation in this case is used to simulate the effect of the photolithographic process. The transformations or functions that define the model can be but are not limited to; physics-based models which use knowledge of the optical and chemical process, machine learning/neural networks (ML/NN) based models where the training data is required to determine the transform or function, semi-empirical approximations, any hybrid combination of the previous. In the physics-based approach, the model is generated by considering transformations or functions which can describe a photolithographic or similar optical process. In the purely data-driven approach, the model is generated by training a generalised function or transform using the training data acquired from the fabrication process, where after training the model performs the mapping of the input data to the output data.

An example of a model (or transform) of the fabrication process 506 may include a circularly symmetric conical filter kernel, to be used with a convolution operation on the initial design, where the conical filter kernel has associated parameters that describe the height of the cone and amplitudes of sinusoidal correction terms, where the set of parameters can be determined for a plurality of sets of training data in fabrication process training data 504. The parameters may be considered to be fabrication model parameters.

A kernel as described herein means a small matrix used in image processing together with the convolution operation such that each pixel in the output image is a function of its neighbouring pixels from the input image. A conical filter with sinusoidal correction terms here means a two-dimensional function of the form:

$$h ( x , y ) = {a}_{0} * w ( x , y ) + {\sum }_{n = 1}^{N} {a}_{n} cos ( {f}_{n} \sqrt{{x}^{2} + {y}^{2}} )$$

$$where$$

$$w ( x , y ) = \{ \begin{matrix}1 - \frac{\sqrt{{x}^{2} + {y}^{2}}}{R} , & \sqrt{{x}^{2} + {y}^{2}} < R \\ 0 , & otherwise\end{matrix}$$

with R being the radius of the conical filter, where a₀ is the height of the cone, aₙ are the amplitudes of the corrections terms to the height of the cone with frequency fₙ.

Training the fabrication model in this case may include performing fits of model parameters. In the example above, a set of parameters describing the cone height and sinusoid amplitudes can be generated by fitting the model using one of a plurality of processed SEM images and the design of that pattern. Fitting the model in this context refers to finding the set of parameters which given the input design, give an output image which has the minimum difference between the modelled output and the processed SEM image. The processed SEM image here refers to an SEM image, typically being a greyscale image, that has been binarized to allow for direct comparison to the binary training pattern design. Training the model in this case refers to fitting a set of parameters for each of the plurality of images in the training data, to generate a statistical model based on the set of fitted parameters. In other cases, neural-network (NN) architectures may be used to train a NN model based on a particular set of training data. The NN architecture may be a pure convolutional-NN (CNN) consisting of series of convolution and transposed convolution layers. In other cases, Variational Autoencoder (VAE) model based on CNN model which allows for random sampling may be used. In other cases, other NN architectures such U-Nets, HPU-Nets, conditional HPU-Nets, as well as combinations of these models with a physics-based or semi-empirical model can be used.

In the example above, application of the model requires sampling the statistical model to receive a set of parameters which can be used to define a particular instance of the kernel. The kernel is convolved with the structural parameters of the photonic device in the simulated environment to perform the fabrication simulation, such that a new set of structural parameters are generated, to be simulated as the as fabricated device. In some cases, instead of sampling the statistical model, a set of mean kernel parameters can be determined to create a mean kernel. This has the effect of simulating the mean expected output of the fabrication process model when convolved with the structural parameters of the photonic device in the simulation environment. This has the benefit of only requiring a single set of parameters to be used to define a single kernel. In this example, the fabrication process model takes an input of the structural parameters of the photonic device in the simulated environment and provides an output set of structural parameters of the photonic device in the simulated environment which is the result of a transformation described by the kernel and a convolution operation.

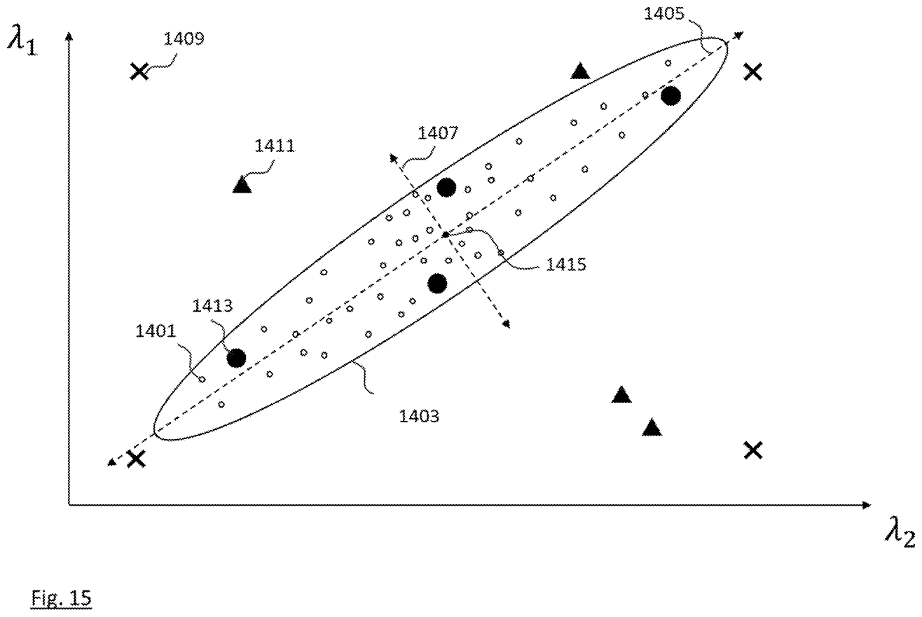

In other cases, sampling the model involves first performing a principal component analysis (PCA) of the parameters of the statistical model to generate a set of parameters which may reduce the dimensionality required to sample the model. The use of the PCA allows the fabrication model to be sampled with fewer parameters while still being able to describe most of the observed variation in the statistical model. This allows sampling of the model with a small dimensionality of parameters while having a fabrication model which has been trained with a high dimensionality of parameters and still being able to access most of the information. Methods of performing principal component analysis for determining multiple sets of sampled parameters for multiple sampled fabrication models, which are to be used in optimising the design of a photonic component, are described in detail later with reference to FIG. 15.

When considering the design and simulation of a photonic component scattering EM waves out-of-plane, such as the commonly used grating coupler, it is appreciated that simulation generally proceeds in the first case in 2D from a “side-view” of the photonic component, since a “top-down” view may not be useful. The “side-view” terminology used here refers to the orientation of the simulation environment such the out-of-plane scattering direction is aligned with the vertical direction (of the 2D plane), and the direction of propagation on the EM wave in the waveguide in the simulated environment is aligned with the horizontal direction (of the 2D plane). In such cases, another example of a model of a fabrication process 506 may be multidimensional statistical model which relates input parameters such as, but not limited to, feature size, etch density and etch depth, to output parameters such as, but not limited to, feature size, etch depth and sidewall angle, where the sidewall angle may be the angle between the side wall and the vertical direction of the 2D plane. The statistical model which relates the input data to the output data may be trained using a one or more training data sets such as, but not limited to, critical-dimension SEM (CD-SEM) images recorded from fabricated training patterns which vary feature size, etch depth and pattern density. The output data value may then be coupled with one or more input parameters.

In FIG. 7 there is shown an illustration of an example training pattern 600 which may be one of a plurality of similar, or dissimilar, training patterns which form a set of training patterns, such as training patterns 502. The illustration of the training pattern 600 is in the cross-sectional view of the lateral plane of an active layer.

Training pattern 600 includes a first material 602 (shown in black), analogous to the first material 312 of FIG. 4, and a second material 604 (shown in white), analogous to the second material 314 in FIG. 4. The first material 602 and the second material 604 are disposed in a significantly inhomogeneous fashion to form a plurality of interfaces 606 which collectively form the training pattern 600. More specifically, the first material 602 and the second material 604 may be disposed such that there is a plurality of islands of the first material 602 of varying structure, typically irregular, and dimension, potentially formed with a plurality of spatial frequencies. There may also be a plurality of inhomogeneously disposed regions of the first material 602 and the second material 604 which comprise regions of interfaces 606 with a high spatial frequency adjacent to regions of interfaces 606 with low spatial frequency. In some cases, the plurality of interfaces 606 can be determined by implementation of Simplex and Perlin noise, which is a subset of Lattice Gradient Noise and can give control over statistical properties of the noise, in combination with a threshold/binarization function. In general, the plurality of interfaces 606 may be generated by utilising a combination of any noise generation function and any thresholding/binarization operation. A noise generation function which has a plurality of control parameters may be used to generate training patterns 600 which have a plurality of distinct features, relating to the features of the noise generation function. Such features include, but are not limited to, regions of high spatial frequency adjacent to regions of low spatial frequency, granularity, gain, lacunarity and fill-factor. A threshold/binarization function is used to map the output of the noise generation function to the plurality of interfaces 606 which is formed from the first material 602 and the second material 604. Noise functions with features described above, and the ability to vary said features, allow training patterns to be generated to discriminate a plurality of effects in the physical fabrication process which are not typically discriminated in a “standard” approach to fabrication process characterisation. Standard photonic device designs heavily feature rectilinear shapes and are typically regularly structured. The current methods to determine characteristic effects of a fabrication process are then typically based on such regular features. In contrast, features of a photonic device designed using the inverse design method are typically significantly inhomogeneous with many free-form curves in the resulting shape. It is therefore a major benefit when generating a model for the fabrication process, to be used in an inverse design approach to optimising the structural parameters of a photonic device, to be able to describe the effects relating to such free-form shapes and significantly inhomogeneous patterns. Consequently, it is necessary to have a set of training patterns which can inform, through physical characterisation, effects relating to such features. The approach taken here is such that it is possible to capture a wide variety of fabrication effects with some (relatively low) number of training patterns. Other choices for noise functions can be limited in the range and proximity of distinct spatial frequencies, which can limit the information provided to the fabrication process model and thus limits the space of real physical effects that can be accounted for during the optimisation procedure.

The dimension of training pattern 600 may be controlled and can be pre-determined. In some cases, the training pattern 600 may span an area of 10 μm by 10 μm. In other cases, it may be smaller, such as 5 am by 5 μm, or bigger, such as 20 am by 20 μm.

Training pattern 600 includes a minimum of three, preferably four, alignment markers 608, disposed around the pattern. Alignment features 608 may be used to uniquely determine a transform that overlays a training pattern 600 with a measured image of a fabricated version of a training pattern 600.

Training pattern 600 may additionally include regions 610 of the first material 602 which are disposed homogeneously with the second material 604, such that the regions 610 may form structures like a waveguide or other related homogenous structures of interest. The structure and dimension of the homogeneous regions of the first material 602 may be like the typical dimensions of a photonic waveguide, such as having a width of 500 nm, or 100 nm-1000 nm. In other cases, the regions 610 of the homogeneously disposed first material 602 may have other dimensions and structure. The inclusion of waveguide-like structures to the training patterns is specifically chosen to provide a baseline for rectilinear features in the training of the fabrication process model. This will prevent an over representation of effects in the model relating to significantly inhomogeneous structures. Moreover, it allows the combination of more “standard” approaches to characterisation of the fabrication process effects, within the same training pattern which allows fewer training patterns to be used overall.

The first material 602 of the training pattern 600 may be the full thickness of the active layer, formed after etching away of voids which are subsequently backfilled to form the second material 604. Such a thickness may be 220 nm. The first material may also be any thickness between the full active layer thickness and the full etch void, e.g., it may correspond to a thickness resulting from a partial etch of the active layer, which might be a thickness 150 nm. In general, there may be regions of the first material 602 and the second material 604, where a plurality of regions of the first material 602 have a distinct thickness of the active layer that can be different from adjacent regions. The inclusion of training patterns for different distinct thicknesses of the active layer is specifically to capture effects of the fabrication process which are related to the different processing stages, which correspond to the different etch depths of the active layer.

In the example shown in FIG. 7, training pattern 600 is formed of two distinct materials, the first material 602 and the second material 604. In other cases, training pattern 600 may include any number of additional materials which may be related to different stages of a multi-layer semiconductor fabrication process. Training patterns for materials or layers relating to different stages of the fabrication process can be included to specifically capture features of the fabrication process which are directly related to the specific material or layer. In general, it is expected that the processing of different materials or layers will have specific effects which are unique to that material or layer, and therefore the information relating to these effects can only be captured when specifically discriminating those features and effects.

It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example. Such features may include, but are not limited to any one or more of:
i) Any type of noise function combined with a thresholding operation.
ii) Patterns can be either all noise based, or all waveguide-like pattern based, but preferably inhomogeneous patterns for use in inverse design.
iii) Training patterns can be defined using any method that can output free-form curves/shapes or rectilinear shapes.
iv) Training patterns can be defined for any layer in the fabrication process that corresponds to a layer in the design rules.
v) Training patterns can be any size, aspect ratio or fill factor.
vi) Alignment features can be any shape from which a centre-of-mass can be determined.
vii) Training patterns may contain any density of the first material relative to the second material.

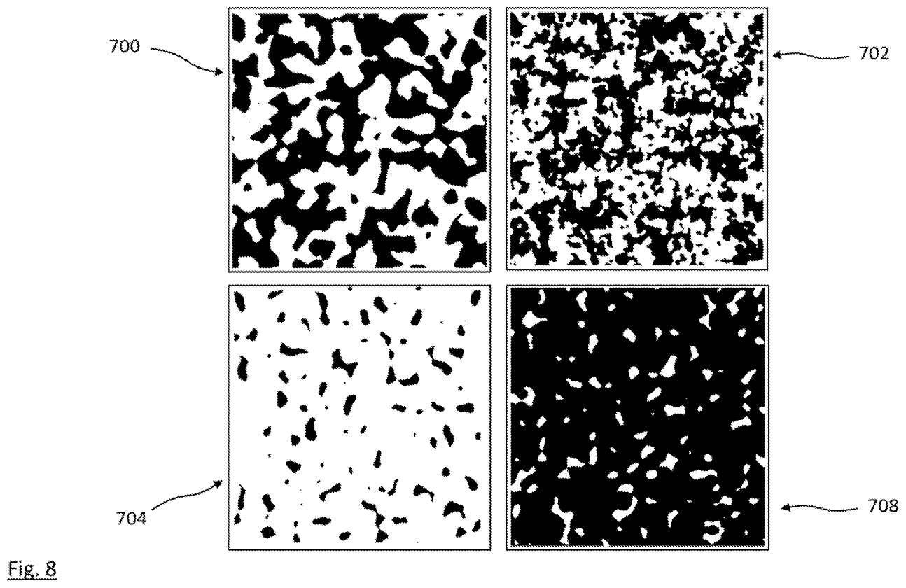

In FIG. 8 there is shown a more detailed example of training patterns 502, which comprise a plurality of different training pattern 600 determined using Simplex and Perlin noise generation function combined with a threshold/binarization function, for different control parameters of the noise generation function.

Training pattern 700 shows an example of the structure of the first material 602 and the second material 604 where one set of noise generation parameters has been used and an average fill-factor of the first material 602 and the second material 604 is 0.5.

Training pattern 702 shows an example structure of the first material 602 and the second material 604 where a different set of noise parameters to 700 has been used and an average fill-factor of the first material 602 and the second material 604 is 0.5.

Training pattern 704 shows an example structure of the first material 602 and the second material 604 where a different set of noise parameters to 700 and 702 has been used and an average fill-factor of the first material 602 and the second material 604 is 0.9.

Training pattern 706 shows an example structure of the first material 602 and the second material 604 where a similar set of noise parameters to 704 has been used and an average fill-factor of the first material 602 and the second material 604 is 0.1.

A set of training patterns 502 may include a plurality of training patterns 600 which have a pre-determined set of noise control parameters and fill factors, such that training patterns 700, 702, 704 and 706 may be valid.

It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example.

FIG. 8 shows some example results of using different noise parameters and fill factors to generate training patterns. Any set of noise parameters can in principle be used but some will be more instructive than others for generating the types of patterns we are interested in.

A set of training patterns may cover a range of noise parameters, sizes, fill factors, etch depths etc.

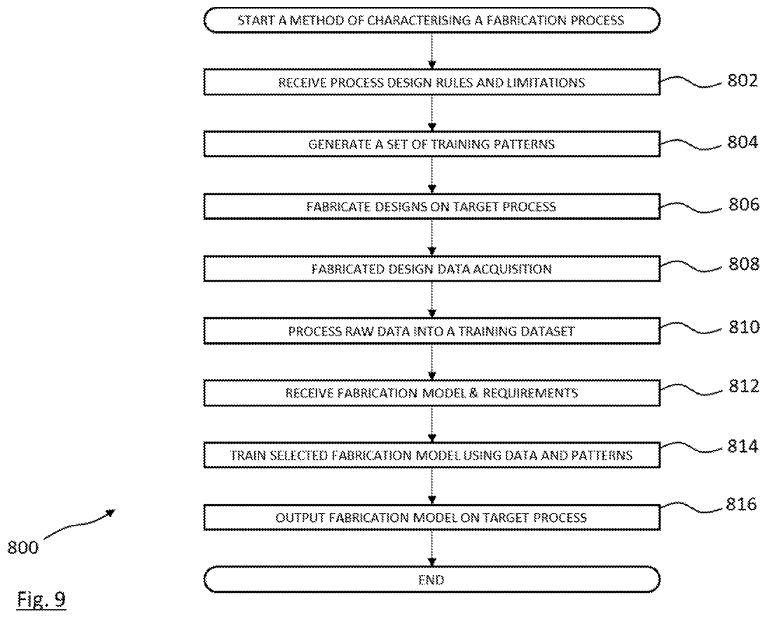

In FIG. 9 there is shown a flow diagram which illustrates a method 800 to generate a fabrication model 506 which is a component of a fabrication transform tool 500, which can be used in a photonic device simulator 400. Photonic device simulator 400 can be used in principle to design a photonic device, such as optical power splitter 100.

A method 800 to characterise a fabrication process and produce a fabrication model of that process proceeds from a start block to block 802 where process design rules and limitations are received from the target process. Process design rules may contain, amongst other things, restrictions or constraints to the minimum feature size, active layer thickness, partial etch layer thicknesses, design file layer specifications (e.g., GDSII format design files contain layer specifications in the format (x,y) where x is the layer number and y is the datatype of that layer).

From block 802, the method 800 proceeds to block 804 where a set of training patterns are generated for the target process using the design rules from block 802. A set of training patterns in this case may comprise of training patterns like training pattern 600 (or like those in the set 700-704), generated through the combination of a noise function and a threshold/binarization function, where each training pattern in the set contains a minimum of three alignment markers, or a minimum of four alignment markers, such as alignment markers 608. The set of training patterns generated in block 804 may be comprised of a plurality of training patterns with a plurality of dimensions, noise control parameters and fill factors. The set of training patterns generated in block 804 may further include a plurality of sets of training patterns which have been specified by different process layers. In some cases, there could be a set of training patterns corresponding to a first etch of an active layer of a semiconductor process and a set which correspond to a second etch of an active layer of a semiconductor process. In general, there can be a set of training patterns for each layer, or combination of layers, specified in the design rules received in block 802. The set of training patterns generated in block 804 may further include sets of designs of traditional photolithography calibration structures. The set of training patterns generated in block 804 may further include optical test structures. In general, the set of training patterns generated by block 804 includes elements that enable the elements the fabrication process training data 504 to be determined through physical measurement.

From block 804, method 800 proceeds to block 806 where the set of training patterns from 804 are fabricated on the target semiconductor process. In some cases, the fabrication process is terminated before the cladding layer (e.g., cladding layer 236) and backfilling step is completed. The fabricated training patterns then comprise regions of the active layer (e.g., active layer 234) and voids which are the result of potentially a plurality of chemical etches of the active layer or hard mask. Omission of the cladding layer and backfilling enables some types of physical measurement of the fabricated structure, e.g., using an SEM or AFM.

From block 806, method 800 proceeds to block 808 where the training patterns fabricated during block 806 are physically measured, generating raw data. In some cases, physical measurements of the training patterns are done by recording SEM images for each training pattern in the set, or subset, of training patterns. In other cases, physical measurement is done by AFM imaging. In other cases, physical measurement includes optical measurements of photonic devices. In general, any way to physically determine characteristics of the fabricated structures can be used to generate the raw data. The raw data may additionally include data received from the manufacturer of the fabricated designs, measured through techniques such as ellipsometry.

From block 808, method 800 proceeds to block 810 where the raw data acquired from block 808 is processed into a set of training data. In some cases, processing the data involves performing a contour finding routine followed by thresholding and binarization of SEM images to transform greyscale image data into binary mask data. It may further include performing transforms to align SEM images with the original design file. The images may further be processed using data augmentation methods to segment sets of SEM images into a larger dataset. In general, processing data into a training data set involves a plurality of methods for a plurality of input data types. The appropriate data processing technique will depend on the type of desired training data.

From block 810, method 800 proceeds to block 812 where the fabrication model and requirements are received. Such a fabrication model may be model of the fabrication process 506, which can be one or more of a plurality of models capable of outputting a set of instructions to perform a fabrication simulation of structural parameters of a photonic device in a simulation environment. In some cases, a fabrication process model may be generated by defining a circularly symmetric conical filter kernel with parameters that describe the height of the cone and amplitudes of sinusoidal correction terms which performs a fabrication simulation when convolved with the structural parameters of the photonic device in the simulated environment, for a given set of parameters defining the kernel. In other cases, a fabrication model may be defined using a coupled multidimensional model which relates a set of input data values to a set of output data values. This method may be used with principal component analysis (PCA) which is described in detail later on. Requirements received may include instructions as to the type of training data compatible with the fabrication model, parameters for the training of the model or any other information relevant to the model.

From block 812, method 800 proceeds to block 814 where the fabrication model received in block 812 is trained using the training data determined in block 810 and the input training pattern designs determined during block 804. Training the fabrication model may include performing fits of model parameters. In some cases, a set of parameters describing the cone height and sinusoid amplitudes can be generated by fitting the model using one of a plurality of processed SEM images and the mask design of that pattern. Fitting the model in this context refers to finding the set of parameters which given the input mask design, give an output mask which has the minimum difference between the modelled output and the processed SEM image. Training the model in this case refers to fitting a set of parameters for each of the plurality of images in the training data, then generating a statistical model based on the set of fitted parameters. In other cases, neural-network (NN) architectures may be used to train a NN model based on a particular set of training data. The NN architecture may be a pure convolutional-NN (CNN) consisting of series of convolution and transposed convolution layers. In other cases, Variational Autoencoder (VAE) model based on CNN model which allows for random sampling may be used. In other cases, other NN architectures such U-Nets, HPU-Nets, conditional HPU-Nets, as well as combinations of these models with a physics-based or semi-empirical model can be used. In other cases, fitting the model may be done by fitting data to a multidimensional function where the output data value is a function of the N-dimensional input data values. This method may be used with principal component analysis (PCA) which is described in detail later on.

From block 814, method 800 proceeds to block 816 where the trained fabrication model is output before proceeding to an end block which terminates the method 800. The model of the fabrication process generated by method 800 will be specific to that fabrication process. In general, the blocks of method 800 may be repeated over multiple iterations of fabrication, measurement, and training, such that the mode of that fabrication process can be continuously updated with new data sets.

The output fabrication model generated by method 800 can be used as part of the larger photonic device simulator 400, but it can more generally be used to simulate the effect of fabrication of an input physical device.

It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example. Such features may include, but are not limited to any one or more of:
i) Training patterns may not be required to use the design rules of the target fabrication process, e.g., they may include features below the minimum stated feature size.
ii) Training patterns can be defined using any method that can output free-form curves/shapes or rectilinear shapes.
iii) Training patterns can be defined for any layer in the fabrication process that corresponds to a layer in the design rules.
iv) Raw data of the fabricated training patterns may be acquired by any method.
v) Raw data of the fabricated training patterns may be processed in any suitable way to allow comparison to the target training pattern design.
vi) The model of the fabrication process can be any trainable transformation or generalised function which takes input data that can be used to define a mask for a fabrication process and outputs data which can be used to define a mask for a fabrication process.
vii) The trained model of the fabrication process may be sampled to determine a first transformation or generalised function which is different from another sample used to determine a second particular transformation or generalised function.
viii) The model can be trained using any data acquired from the real target fabrication process.
ix) The training data can be acquired using any method which determines physical properties of the fabrication process.

During step 814, a fabrication model may be trained on a large number of sets of training data. For each set of training data, the fabrication model may have associated with it fabrication model parameters which determine how the fabrication model turns input data into a given output data. For example, a fabrication model (e.g. a kernel) may be trained on a vast quantity of SEM images of training pattern samples, where each sample SEM image provides a set of training data representing the output of the fabrication process for that sample. For each sample, the kernel has a set of fitted fabrication model parameters which define the kernel such that, when the kernel is used on an image of an initial design, a simulated output corresponding to the real sampled SEM-imaged output is generated. It is therefore possible to produce many samples of fabrication models, each with their own parameters, which describe a fabrication process. In order to optimise the design of a photonic component using inverse design, it may be preferable to sample over a distribution of fabrication models (and their associated parameters) such that either i) an average fabrication model can be determined and used in the optimisation of the photonic component, or ii) a set of sample fabrication models, which accurately represent the variation of the fabrication process, can be determined and used to optimise the design of the photonic component. A useful method which may reduce the amount of sampling required is principal component analysis, which is described below in relation to the current method.

FIG. 15 shows a space of fabrication model parameters to which principal component analysis (PCA) may be applied to obtain a new set of basis vectors. Sampling along the new basis vectors may yield more physically-significant combinations of parameters, or yield combinations of parameters which are more likely to appear using the given fabrication model. Building a distribution of these parameters, using a sampling method, may be performed more efficiently when these new basis vectors are known. The graph of FIG. 15 has a y-axis which corresponds to parameter λ₁, and an x-axis which corresponds to parameter λ₂. The axes labelled by λ₁ and λ₁ may correspond to any parameter of the fabrication model. Some non-exhaustive examples of such parameters, which may also be physical parameters, include surface wall roughness, refractive wall index, etch depth, etc. The parameters may also be computational parameters, such as by a₀ and aₙ which define a kernel, where the kernel is used in a convolution with an initial design (which may be in the form of an SEM image) to binarise and transform the design to emulate a photonic component designed using the fabrication model. If the transform model is a neural network, for example, the parameters may represent different weights.

The fabrication model may produce samples 1401 related to a potential fabrication output (e.g. photonic component, training pattern) which have associated parameters. These parameters for each sample may be measured by any suitable means, for example by using SEM imaging if they are physical parameters. The parameters may show a correlation based on the limitations of the fabrication model—for example, most of the samples shown in FIG. 15 exist in the elliptical sub-space 1403 of the parameter space, where the ellipse 1403 may represent a skewed 2D Gaussian distribution. This behaviour may be likened to a simple example unrelated to photonic components, wherein the heights (e.g. λ₁) and weights (e.g. λ₂) of individual people (e.g. samples 1401) are seen to show a strong linear correlation, where a greater height will typically provide a larger weight of the individual, with some variation along the main direction of correlation (e.g. a tall, skinny person or a short, fat person). Similarly, we may attribute a first principal component 1405 along the direction in the space of parameters which corresponds to the direction of greatest variance among the samples, shown along the major axis of the ellipse 1403. A second principal component 1407 along the direction corresponding to the direction of second-greatest variance among samples may also be determined, shown along the minor axis of the ellipse 1403. The direction of the second-greatest variance may be orthogonal to the direction of the first principal component. The principal components may be determined by performing the PCA method. The PCA method may be any PCA method which is known in the art.

Once the first and second principal components are determined, a new set of basis vectors may be determined. They may be determined by a change of basis of the axes, which may be a rotation. The new axes may have associated with them new parameters which may be expressed as a linear combination of the original parameters, λ₁ and λ₁. It is along these basis vectors that more efficient sampling of the parameter space may be performed. This sampling may use any sampling method, such as a Sobol sequence, which samples the parameter space to build a statistical model, which may allow determination of average parameter values which correspond to an average fabrication model. Inefficient sampling, not using PCA or the sampling method (e.g. Sobol sequence), is shown with cross-shaped sampling points 1409, which have sampled extreme regions of the parameter space for which no real samples may actually exist. This may correspond, for example, to the etch depth (e.g. λ₂) corresponding to the minimum resolution of features (e.g. λ₂), where it may be physically impossible to have a small etch depth for a large minimum resolution of features. An example of random sampling is shown with triangular sampling points 1411, where the sampling may still span a space which does not include the space which real samples are likely or possible. Using PCA, we may sample along the space defined by the first principal component 1405 and the second principal component 1407, allowing us to efficiently sample a space where more physically significant samples are located. Such sampling is shown with sampling points 1413.

For simplicity, the graph shown is 2-dimensional, and as such is only capable of displaying the relationship between 2 parameters for each sample taken; however, there may be more than 2 parameters measured, such as 20, 30, or 40 parameters, for example. As the dimensionality of the parameter space increases, the more likely it is that random sampling will not yield any physically significant combinations of parameters. As such, the benefit of using PCA also increases significantly.

A benefit of using PCA is that it is possible to determine the most important dimensions to sample across, which may allow the dimensionality of the sampling space to be reduced, increasing the efficiency of the sampling method (e.g. Sobol sequence). Using FIG. 15 as an example, the main variation of the samples occurs along the first principal component 1405. Therefore, if samples were to be taken only along the direction of the first principal component, a significant number of high-quality samples may still be obtained, whilst reducing the computational requirements of also sampling along the second principal component. In some instances, where the initial dimensionality of the space is relatively low (5-10 dimensions, for example), it may be preferable not to reduce the dimensionality, but still sample using PCA, as reducing it limits the sampling space which may be sampled over, limiting the quality of the sampling. However, for higher numbers of dimensions, e.g. 30, it may be preferable to reduce the number of dimensions using PCA. In an example where a 30-dimensional space is reduced to a 7-dimensional space, only the first 7 principal components may be sampled over.

The number of principle components sampled over may be a number that captures a significant fraction of the variation in the fabrication process model parameter data values. Taking a simplified example, where the number of dimensions of the parameter space may be, for example, 10, then it may be that sampling over the first principal component accesses 40% of the variation, sampling over the second principal component accesses another 30% of the variation, sampling over the third principal component accesses another 20% of the variation, etc. In this example, although sampling over all principal components up to the 10^{th} principal component allows us to eventually access 100% of the variation, it may be beneficial to reduce the dimensionality to 3, such that we can access 90% of the variation (40%+30%+20%), providing a high quality of sampling. The minimum level of variation may be chosen in any way to be any number. For example, the number of principal components to sample over may be chosen such that the sampling covers between, for example, 50 to 100% of the variation of data. The number of samples may be chosen so that at least 90% of the variation in the fabrication process model parameter data values is captured, more preferably 95% of the variation, even more preferably 99% of the variation.

The Sobol sequence is particularly advantageous to apply to the samples after performing PCA, as it is a low-discrepancy quasi-random sampling method which uniformly samples the parameters across the sampling space to ensure that outlier samples are captured in the sampling. This may be beneficial over a Monte-Carlo method of sampling, which may have a bias around sampling the most commonly sampled points. Other low-discrepancy quasi-random sampling methods may be used.

This method may be performed as part of method step 1108 for each fabrication model. The samples of fabrication models may be chosen such that the variance of the distribution is adequately represented, with samples being taken from different parts of the elliptical sub-space 1403 so that the optimisation method 1100 can take into account the many effects of the specific fabrication process used to fabricate the photonic component. This method may also be used to generate the average fabrication model of step 1008 of method 1000 by using an average of the typical parameters which may be produced from a fabrication process. Applying this average fabrication model to an initial design may result in a design which emulates what would be expected of an average application of the fabrication transform. In the present example, if we assume a 2D Gaussian distribution, then the parameters of the average fabrication model may be represented in parameter space as the small black dot 1415 in the middle of the 2D Gaussian distribution. The distribution may not be Gaussian, but is assumed to be for ease of explanation in this example.

Once the sampling has been conducted, the samples of fabrication models or average fabrication model may then be used in the inverse design process (including simulating the component) to optimise the design of the component.

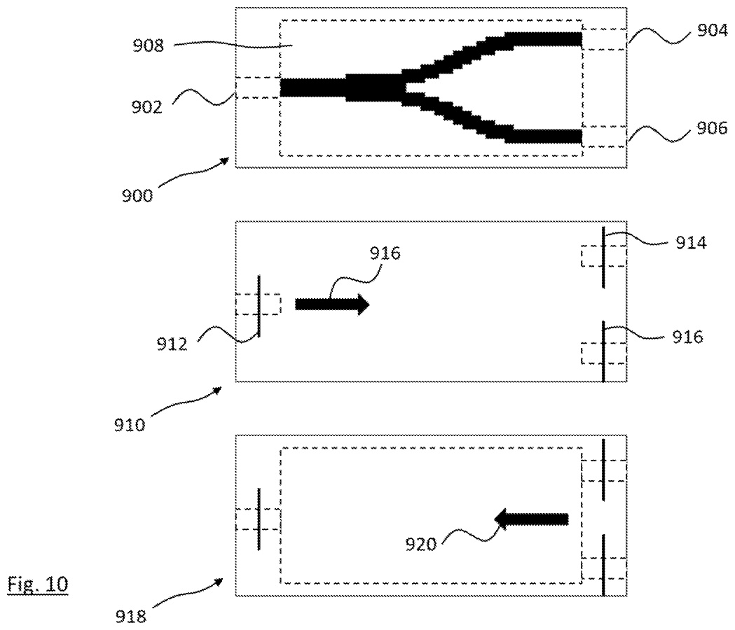

In FIG. 10 there is shown an illustration of the configuration of the simulation environment which includes the demonstrative setup of simulation environment 900 which describes a photonic device, such an optical power splitter, the configuration of the operational simulation 910 and the configuration of the adjoint simulation 918. The represented simulation environment may be implemented by a computer system as part of a photonic device simulator 400. The simulation environment illustrated in FIG. 10 is shown in two dimensions, however, other dimensionality may be used to describe the simulated environment, e.g., 3-dimensional space. In some cases, the physical parameters of a photonic device described by structural parameters in the configured simulation environment of FIG. 10 may be optimised by an inverse design process which includes performing an operational simulation and an adjoint simulation which may utilise the finite-difference time-domain (FDTD) method to model the electromagnetic field response to an excitation source.

An example of a demonstrative setup of the simulation environment 900 illustrates how a photonic device, such as an optical power splitter, may be configured in the simulation environment. The simulation environment contains an input region 902, like input region 302, a plurality of output regions 904 and 906, like the plurality of outputs regions 304 and 306, and a design region 908 like dispersive region 320. After receiving an initial description of the photonic device, described by one or more physical parameters, the simulation environment is configured with a set of corresponding structural parameters, representative of the photonic device. In some cases, the physical parameters correspond to directly to the structural parameters. In other cases, a mapping is used to determine the structural parameters from the physical parameters. The structural parameters of the simulated environment are described by a plurality of voxels of the 2-dimensional (or other dimensional) space, which represent individual elements of the structural parameters. The plurality of voxels in the N-dimensional space corresponds to discretisation of the physical photonic device within the simulated environment. Each voxel of the plurality of voxels in the simulated environment can be associated with at least a material value, an electromagnetic field value and a source value. The material values may correspond to a relative permittivity, permeability or refractive index that collectively describe the material interfaces/boundaries of the photonic device in the simulated environment, determined from the structural parameters. The electromagnetic field value of the voxel describes the electromagnetic field response that is calculated using Maxwell's equations in response to excitation described by the source value at a particular time step of the propagation of the electromagnetic field in the simulated environment. The electromagnetic field value may be associated with the magnetic field, the electric field, or some combination of both (e.g. Poynting vector, intensity). If the FDTD method is used, there may be multiple of the same type of electromagnetic field associated with each voxel. The field response is therefore based, in part, on the material value determined by the structural parameters and the source value. The physical parameters of the photonic device, which are subsequently mapped to the structural parameters in the simulated environment can be updated or revised, possibly using inverse design process and iterative gradient-based optimisation based on a loss function used to quantify the performance of the photonic device in the simulated environment, such as a loss function used to describe the operation of an asymmetric optical power splitter, e.g., optical power splitter 100.

The configuration of the operational simulation 910 illustrates how an operation simulation is performed in the simulated environment 900. An operational simulation is used to determine a field response of a configured set of structural parameters in response to an excitation or source value, which is calculated by solving Maxwell's electromagnetic field equations over a plurality of time steps. The operational simulation contains the structural parameters which describe the photonic device, described by the plurality of N-dimensional voxels. The operational simulation additionally contains one or more excitation inputs regions 912, which are located within the input regions 902, which define the excitation source signal 916 (e.g., Gaussian pulse, waveguide mode, etc) that is input to the simulation and propagated over a plurality of time steps. The excitation source signal 916 at one particular time step causes a response in the field values which are related to the structural parameters, as well as the field response value of the prior time step. This is because Maxwell's equations may be solved using both the time and spatial derivatives of the electromagnetic field, and in a simulation with discretised time steps it may be necessary to calculate time derivatives of the field by using the field values at two different time steps. In some cases, the plurality of voxels which contains the source values can be updated over the plurality of time steps, such that a spatial or time-dependent behaviour of the input excitation source signal can be described in the simulated environment. The time step is incremented with the field response being calculated at each step, such that over the plurality of time steps, the excitation source signal is propagated over the design region 908 to the plurality of output regions 904 and 906. The plurality of output regions 904 and 906 may additionally include excitation output regions 914 and 916, which can be used to determine a steady state of the simulation, or a stop condition for the time stepping of the field response. After the plurality of time steps, the changes to the field values in response to the excitation source may have either reached a steady state or stabilised to a negligible value. The operational simulation can then be terminated, and one or more performance metrics may be calculated using the field response values. Such a performance metric may be the power transmitted from the input excitation region 912 to output excitation region 914 and 916, potentially over a plurality of spatial and temporal profiles. The performance metric can be further used to quantify the performance of the photonic device in relation to a target performance by inclusion of the performance metric in a loss function. E.g., the target performance metric could be to have 70% of the input optical power of the fundamental transverse-electric waveguide mode at wavelength of 1550 nm transmitted to output region 914, with 30% of the input optical power of the fundamental transverse-electric waveguide mode at wavelength of 1550 nm transmitted to the output region 916. A loss function can be defined, based on this target performance metric and the output performance metric based on the initial input design of the photonic device, to calculate a loss metric. The loss metric, in combination which an adjoint simulation, can be used to determine a structural gradient, that is the effect of the structural parameters on the loss metric, which can further be used to determine the effect of the physical parameters on the loss metric, for the purpose of updating, or otherwise revising, the physical parameters which describe the photonic device. The loss function can include terms which relate to a plurality of features of the design in addition to the target performance metric, e.g., terms associated with the fabricability of the design, which may be related to a minimum feature constraint, or otherwise.

The configuration of the adjoint simulation 918 illustrates how an adjoint simulation is performed based on the configuration of the operational simulation 910 and a loss metric. An adjoint simulation is a backpropagation of a loss metric, which in this context, relates to a time-backwards simulation in which the loss metric is used as an excitation source signal 920 to the simulation. More specifically, an adjoint excitation source is defined using loss metric calculated using the field response of the operational simulation at the output excitation regions 914 and 916. The adjoint simulation source is then used as an input to the simulation at the excitation output regions 914 and 916 and propagated to the excitation input region 912, which effectively performs a time-backwards simulation of the loss metric. After definition of the adjoint excitation source, the adjoint simulation is performed similarly to the operational simulation. From the perspective of the calculation of Maxwell's equations to update the field values at a particular time step, the problem is the same as for the operational simulation. After time stepping of the adjoint simulation terminates, the field response values can be used to determine the structural gradient, which measures how the structural parameters influence the loss metric. The structural gradient can then be backpropagated, if necessary, to determine the gradient with respect to the physical parameters, such that the influence of the physical parameters of the photonic device can be related to the loss metric. The physical parameter gradients can be used to update the physical parameters to reduce the loss metric and therefore generated an updated, or otherwise revised, description or design of the photonic device.

The iterative cycle of using the operational simulation and the adjoint simulation to determine the gradients of the physical parameters and updating the physical parameters to revise the design of the photonic device to reduce the loss metric form the basis of the inverse design process when used with a gradient-based optimisation scheme. In such a scheme, the physical parameters are revised at each iteration based on the determined gradients. The parameters are then changed incrementally at each iteration to reduce the loss metric, until the loss metric substantially converges or otherwise reaches a threshold value or range which terminates the optimisation scheme.

An effect of designing a photonic device in this way, and with standard ways, is that real fabricated devices perform differently to those which perform ideally under simulated conditions. The difference is attributed to the effect of the fabrication process which cannot be accounted for in a standard inverse design, or otherwise, process for designing a photonic device. The fabrication process can lead to many differences in the physical device compared with simulated device, differences such as sidewall angle (even when accounted for in simulation), erosion, dilation, waveguide thickness, line-edge roughness (LER), material imperfections, effects from misalignment of the optical system, or other optical effects which result from the features on the mask used for fabrication. Additionally, variation in the fabrication process can lead to physical devices where these effects are present to varying degrees, typically over some range. E.g., the level of over/under etch present on the fabricated photonic device may vary between +/−10 nm, or otherwise, from the designed photonic device. In some cases, effects of the fabrication can be largely deterministic, in other cases, the effects of fabrication can be largely stochastic over some range of values. More importantly, the effects of fabrication may vary substantially between different fabrication processes, even on the same material platform, such as an industry standard 220 nm SOI process. In this regard, it is important to have a design process which includes the effects of fabrication. More specifically, it is important to have a design process which includes the effects of the specific fabrication process which will be used to fabricate the photonic devices. What is desired is a design technique which is capable of producing highly performant designs for physical devices which are robust to the specific fabrication process that will be used to create them. It is generally not possible to determine the conditions of the fabrication process to determine under what conditions, or range of conditions, the physical device should be simulated with. Therefore, is it paramount that effect of the fabrication process is treated as independent and separately characterised, such that a model of the fabrication process, such as fabrication model 506 which can be generated using method 800, can be used to appropriately determine a condition under which to simulate the physical photonic device.

It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example. Such features may include, but are not limited to any one or more of:
i) Any method can be used to perform the EM simulations to receive the computer modelled EM field output,
ii) Any loss metric which enables the target performance to be included together with a potentially plurality of penalty terms as part of the optimisation can be used,
iii) Any type of optimisation method/algorithm, which can be gradient or non-gradient based, can be used. In gradient-free optimisation, the adjoint simulation may not be required.

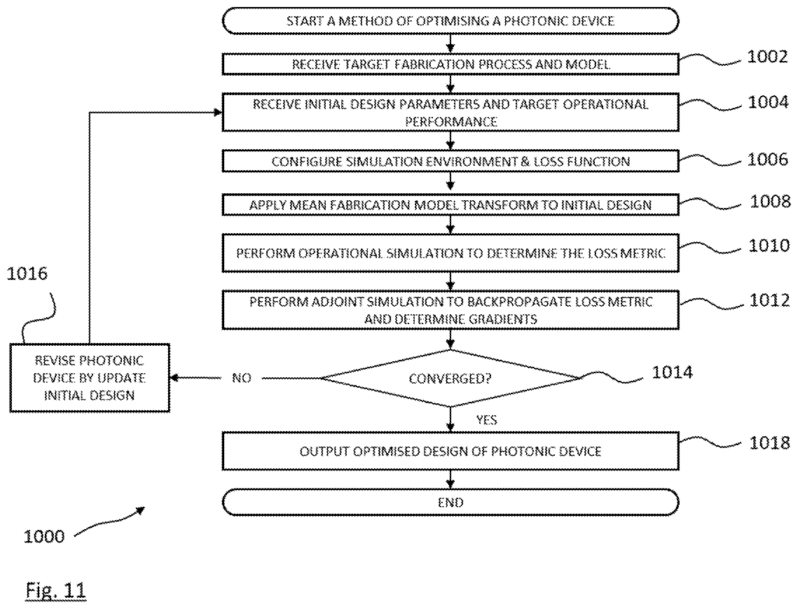

In FIG. 11 there is shown a flow diagram which illustrates a method 1000 to optimise the physical parameters of a photonic device for a specific fabrication process, based on a fabrication model of that specific fabrication process.

From a start block, a method to optimise photonic device 1000 proceeds to a block 1002 which receives a target fabrication process and the associated fabrication model of that fabrication process. The fabrication model may be a model like 506, which has been generated through a characterisation process which may be method 800. The fabrication model provides instructions to simulate the effect of the fabrication of a physical photonic device within a simulation environment, where the photonic device is described by one or more physical parameters, which have been mapped to a plurality of structural parameters which are described by a plurality of voxels within the simulated environment.

From block 1002, a method 1000 proceeds to block 1004 where the initial design of a photonic device and the target operational performance is received. The initial design of the photonic device, e.g., an optical power splitter 100, is described by one or more physical parameters which are mapped to structural parameters of a simulation environment. The target operational performance of the photonic device specifies the function that the photonic device should do, i.e., the response of the electromagnetic field to an excitation source at one or more inputs. The initial design of the photonic device may be specified using one or more physical parameters.

From block 1004, method 1000 proceeds to block 1006 which configures the simulation environment based on the initial design of the photonic device, such as those illustrated in FIG. 10, including the excitation input regions and output regions and input excitation source values. The physical parameters which describe the photonic device are mapped to structural parameters in the simulated environment. The loss function is also defined using the target operational performance of the photonic device. The loss function can be defined in any way such that a loss metric can be determined to quantify the performance of the simulated physical device. The loss function may combine the target operational performance with other functions which determine metrics which might relate to other elements, such as fabricability of the device as determined by a minimum feature size constraint. In general, any number of penalisation terms can be included in the loss function which act to influence the path of an optimisation procedure.

From block 1006, method 1000 proceeds to block 1008 which uses a mean fabrication model to transform the structural parameters of the photonic device in the simulated environment to determine a set of as fabricated structural parameters which correspond to the average expected output of the physical device, using the fabrication process corresponding to the fabrication model. From block 1008, method 1000 proceeds to block 1010 which performs the operational simulation of the photonic device described in the simulation environment, such that after termination of the simulation, the loss metric can be determined using the output electromagnetic field values, structural parameters, and the loss function.

From block 1010, method 1000 proceeds to block 1012 which uses the field values from the operational simulation and the loss metric to define an adjoint simulation. The adjoint simulation is performed which backpropagates the loss metric through the simulation, to determine gradients of the structural parameters which can be subsequently backpropagated to determine gradients of the physical parameters which describe the photonic device.

From block 1012, method 1000 proceeds to decision block 1014 where a determination is made on whether the loss metric has substantially converged such that the operational performance and target operational performance are within a threshold range, or the loss metric which potentially includes a plurality of additional constraints is below a threshold value.

If the decision is NO, the method 1000 proceeds to block 1016 which revises the initial design of the photonic device. The revised physical parameters may be determined independently of the calculated gradients, or through utilisation of the gradients determined in block 1012. In some cases, the revised description may be generated though utilising an optimisation scheme together with a cycle of operational and adjoint simulations and a gradient-based optimisation algorithm, which could be gradient descent. In other cases, another type of gradient or non-gradient-based optimisation scheme may be used to generate a revised set of physical parameters. In general, iterative cycles of operational simulation, adjoint simulation and revision of the physical parameters may be used until the convergence of loss metric is substantial such that the decision at block 1014 exits under the YES condition.

If the decision at block 1014 is a YES, method 1000 proceeds to block 1018 which outputs the optimised physical parameters corresponding to the design of the photonic device before termination of the method.

By using a mean fabrication model to simulate the average expected as fabricated photonic device, the inverse design method can include the average effect of the fabrication process, such that the optimisation is performed under conditions which are closely related to the actual observed conditions from that fabrication process. It therefore enables optimisation of a photonic device which is robust to the specific effects of that fabrication process.

It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example. Such features may include, but are not limited to any one or more of:
i) Any method can be used to perform the EM simulations to receive the computer modelled EM field output,
ii) Any loss metric which enables the target performance to be included together with a potentially plurality of penalty terms as part of the optimisation can be used,
iii) Any type of optimisation method/algorithm, which can be gradient or non-gradient based, can be used. In gradient-free optimisation, the adjoint simulation may not be required.
iv) The single instance of the fabrication process model does not have to correspond the mean or average set of parameters or average expected output. E.g., it could be defined as a worst-case scenario.

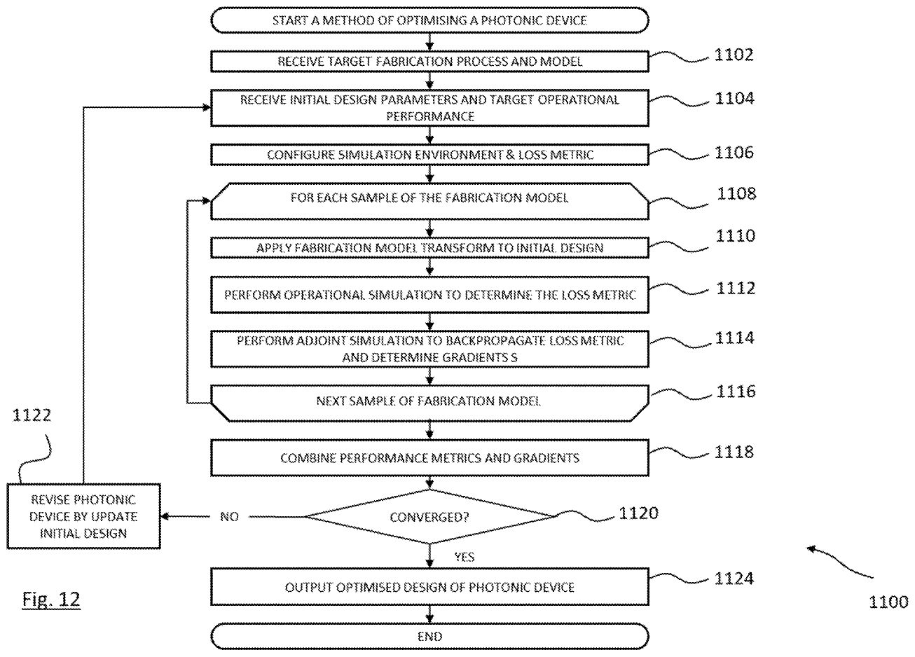

In FIG. 12 there is shown a flow diagram which illustrates a method 1100 to optimise the physical parameters of a photonic device for a specific fabrication process, based on the sampling of a fabrication model of that specific fabrication process.

From a start block, a method to optimise photonic device 1100 proceeds to a block 1102 which receives a target fabrication process and the associated fabrication model of that fabrication process. The fabrication model may be a model like 506, which has been generated through a characterisation process which may be method 800. The fabrication model provides instructions to simulate the effect of the fabrication of a physical photonic device within a simulation environment, where the photonic device is described by one or more physical parameters, which have been mapped to a plurality of structural parameters which are described by a plurality of voxels within the simulated environment.

From block 1102, a method 1100 proceeds to block 1104 where the initial design of a photonic device and the target operational performance is received. The initial design of the photonic device, e.g., an optical power splitter 100, is described by one or more physical parameters which are mapped to structural parameters of a simulation environment. The target operational performance of the photonic device specifies the function that the photonic device should do, i.e., the response of the electromagnetic field to an excitation source at one or more inputs. The initial design of the photonic device may be specified using one or more physical parameters.

From block 1104, method 1100 proceeds to block 1106 which configures the simulation environment based on the initial design of the photonic device, such as those illustrated in FIG. 10, including the excitation input regions and output regions and input excitation source values. The physical parameters which describe the photonic device are mapped to structural parameters in the simulated environment. The loss function is also defined using the target operational performance of the photonic device. The loss function can be defined in any way such that a loss metric can be determined to quantify the performance of the simulated physical device. The loss function may combine the target operational performance with other functions which determine metrics which might relate to other elements, such as fabricability of the device as determined by a minimum feature size constraint. In general, any number of penalisation terms can be included in the loss function which act to influence the path of an optimisation procedure.

From block 1106, method 1000 proceeds to a for loop which is defined by a for-loop start block 1108 and a for-loop end block 1118, where in each loop the fabrication model is sampled to determine a particular instance of the model. In some cases, sampling the model is performing using a quasi-random Sobol sequence after performing a PCA to reduce the dimensionality of the statistical model parameters, such that a uniform sampling of the distribution of parameters which define the fabrication model can be achieved in a way such that extremes of the fabrication model are accessed more readily within a fewer number of samples than a traditional random distribution sampling method, because of the uniformity of the Sobol sequence in the parameter space and the PCA dimensionality reduction preserving most of the variation. In other cases, a Monte-Carlo like approach may be taken to sample the fabrication model. In general, any method of sampling may be used to generate a particular instance of the fabrication model. In some cases, the sampling and simulation cycles described the for loop may be performed using a parallel computing architecture.

Once a sample of the fabrication model has been made to generate an instance of the fabrication model, method 1100 proceeds to block 1110 where the fabrication model is used to transform the structural parameters of the photonic device in the simulated environment to determine a set of as fabricated structural parameters which correspond to one possible output of the physical device, using the fabrication process corresponding to the fabrication model.

From block 1110, method 1100 proceeds to block 1112 which performs the operational simulation of the photonic device described in the simulation environment, such that after termination of the simulation, the loss metric can be determined using the output electromagnetic field values, structural parameters, and the loss function.

From block 1112, method 1100 proceeds to block 1114 which uses the field values from the operational simulation and the loss metric to define an adjoint simulation. The adjoint simulation is performed which backpropagates the loss metric through the simulation, to determine gradients of the structural parameters which can be subsequently backpropagated to determine gradients of the physical parameters which describe the photonic device.

After each sample of the fabrication model has been applied to the initial design, an operational and adjoint simulation performed and the gradients of the physical parameters determined, for loop end block 1116 proceeds to block 1118. In block 1118, the loss metric values and the gradients of the physical parameters for each set of the plurality of loss metrics and sets of gradients of physical parameters corresponding to each sample of the fabrication model are combined into a single loss metric value and single set of gradients for the physical parameters of the photonic device. The combination may be done by a simple statistical averaging. In other cases, the combination may be done using a softmin function (to preserve differentiability) or lower-bound function for a statistical distribution. In general, the combination may be done in any linear or non-linear way to reduce the set of loss metric values to a single loss metric value, and to reduce the sets of gradients of physical parameters to a single set of gradients of the physical parameters.

From block 1118, method 1100 proceeds to decision block 1120 where a determination is made on whether the loss metric has substantially converged such that the operational performance and target operational performance are within a threshold range, or the loss metric which potentially includes a plurality of additional constraints is below a threshold value.

If the decision is NO, the method 1100 proceeds to block 1122 which revises the initial design of the photonic device. The revised physical parameters may be determined independently of the calculated gradients, or through utilisation of the gradients determined in block 1120. In some cases, the revised description may be generated though utilising an optimisation scheme together with a cycle of operational and adjoint simulations and a gradient-based optimisation algorithm, which could be gradient descent. In other cases, another type of gradient or non-gradient-based optimisation scheme may be used to generate a revised set of physical parameters. In general, iterative cycles of operational simulation, adjoint simulation and revision of the physical parameters may be used until the convergence of loss metric is substantial such that the decision at block 1120 exits under the YES condition.

If the decision at block 1120 is a YES, method 1100 proceeds to block 1124 which outputs the optimised physical parameters corresponding to the design of the photonic device before termination of the method.

By sampling from a fabrication model to simulate the variations in expected as fabricated photonic device, the inverse design method can include the variation of the real fabrication process, such that the optimisation is performed under conditions which are closely related to the actual observed conditions from that fabrication process. It therefore enables optimisation of a photonic device which is robust to the specific effects of that fabrication process and the variation expected on that fabrication process.

It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example. Such features may include, but are not limited to any one or more of:
I. Any method can be used to perform the EM simulations to receive the computer modelled EM field output,
II. Any loss metric which enables the target performance to be included together with a potentially plurality of penalty terms as part of the optimisation can be used,
III. Any type of optimisation method/algorithm, which can be gradient or non-gradient based, can be used. In gradient-free optimisation, the adjoint simulation may not be required.
IV. Any method of sampling from the statistical model to define a particular fabrication model can be used,
V. Any method to combine the plurality of loss metrics and gradients, to give a single loss metric value and single set of gradients, can be used.

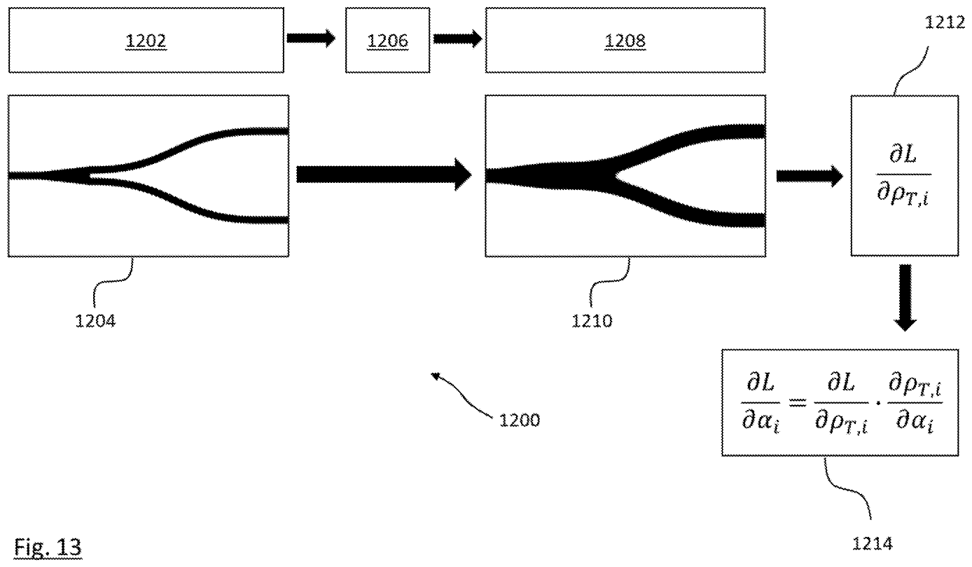

The sensitivity of the performance of a photonic device may also be determined with respect to the fabrication process variations, using a model of the fabrication process. FIG. 13 conceptualises a method 1200 for the determination of the sensitivity of the performance of a photonic device with respect to the fabrication process variations, using a model of the fabrication. The structural parameters of a photonic device in a simulation environment are denoted in FIG. 13 as 1202, and can be represented as ρᵢ or ρ=[ρ₁, ρ₂, . . . , ρ_{N}]. These structural parameters are illustrated in 1204, and are subject to a fabrication model 1206, denoted as T(α₁, α₂, α_{M}, ρ₁, . . . , ρ_{N}), such that the output structural parameters 1208, denoted here as ρ_{T,i}, and illustrated in 1210, correspond to the expected output of structural parameters 1202 after a fabrication process. The fabrication model may be a model like 506, which has been generated through a characterisation process which may be method 800. The fabrication model parameters of the fabrication model 1206, denoted here as αᵢ, encapsulate effects of the fabrication process on the structural parameters ρᵢ, but may, or may not, directly correspond to physical process operating conditions, such as, but not limited to ambient temperature, erosion, dilation, waveguide thickness, structure out of plane, side-wall angle, surface roughness, misalignment, optical aberrations from the mask lithography process, material imperfections and material refractive index. In one example, a fabrication model may include a circularly symmetric conical filter kernel, to be used with a convolution operation, where the associated parameters describe the height of the cone a₀ and amplitudes of sinusoidal correction terms an, where a set of parameters may be determined for a plurality of sets of training data in fabrication process training data 504. The parameters that describe the kernel then form some, but not necessarily all, of the fabrication model parameters αᵢ. In other cases, the fabrication model parameters αᵢ may correspond to changes of features such as, but not limited to, waveguide erosion/dilation, waveguide thickness, waveguide material refractive index, when the fabrication model transformation is applied.

A loss function, L, that describes the performance of the photonic device may be determined from an operational simulation as described previously. An adjoint simulation may be performed which backpropagates the loss metric through the simulation, to determine gradients with respect to the structural parameters, denoted here as: ∂L/∂ρ_{T,i} and in FIG. 13 as 1212. These gradients of the loss function with respect to the structural parameters may be subsequently backpropagated to determine gradients of the physical parameters which describe the photonic device. These gradients with respect to the structural parameters 1212 may also be used in the determination of the gradients of the loss function with respect to the parameters of the fabrication model, shown on the left-hand side of Equation 1 (1214). The gradients of the loss function with respect to the parameters of the fabrication model may be determined by calculating the gradients of the fabrication transformed structural parameters 1208 with respect to the fabrication model parameters, αᵢ, (third term of Equation 2), and applying the chain rule, using the gradients of the loss function with respect to the structural parameters (second term of Equation 1):

$$\frac{\partial L}{\partial {α}_{i}} = \frac{\partial L}{\partial {ρ}_{T , i}} \cdot \frac{\partial {ρ}_{T , i}}{\partial {α}_{i}} \qquad ( Equation 1 )$$

For as long as these gradients (third term of Equation 1) may be determined, which assumes the fabrication model 1206 is differentiable, the resulting gradients of the loss function with respect to the fabrication model parameters (first term of Equation 1) may be determined. This leverages the computationally efficient adjoint method to determine the sensitivity of the performance of a photonic device with respect to a plurality of fabrication process effects, encapsulated by a differentiable fabrication model 1206. It may further add computational efficiency to the method described in FIG. 12, where the fabrication model is sampled many times to obtain corresponding loss metric function values for the plurality of ways a photonic device transforms under a given fabrication process model, which may then indicate how sensitive a current design is to the expected variation in the fabrication process. In the method described in FIG. 13, information about the robustness of the current design may be directly obtained from only one operational and adjoint simulation of the photonics device.

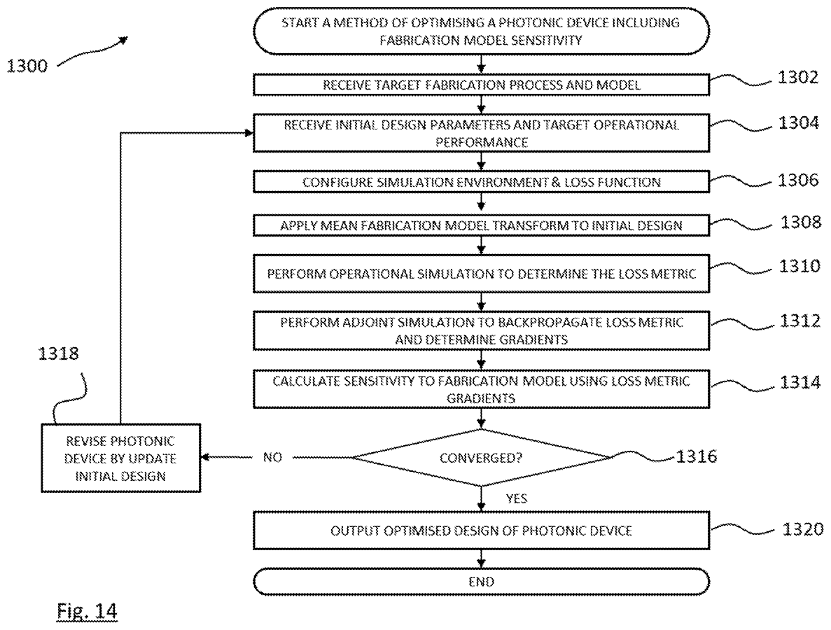

In FIG. 14 there is shown a flow diagram which illustrates an example method 1300 to optimise the physical parameters of a photonic device for a specific fabrication process, based on a fabrication model of that specific fabrication process including sensitivities of the photonic device to the fabrication model.

From a start block, a method to optimise photonic device including fabrication model sensitivity 1300 proceeds to a block 1302 which receives a target fabrication process and the associated fabrication model of that fabrication process. The fabrication model may be a model like 506, which has been generated through a characterisation process which may be method 800. The fabrication model provides instructions to simulate the effect of the fabrication of a physical photonic device within a simulation environment, where the photonic device is described by one or more physical parameters, which have been mapped to a plurality of structural parameters which are described by a plurality of voxels within the simulated environment.

From block 1302, the method 1300 may proceed to block 1304 where the initial design of a photonic device and the target operational performance is received. The initial design of the photonic device, e.g., an optical power splitter 100, may be described by one or more physical parameters which are mapped to structural parameters of a simulation environment. The target operational performance of the photonic device specifies the function that the photonic device should do, i.e., the response of the electromagnetic field to an excitation source at one or more inputs. The initial design of the photonic device may be specified using one or more physical parameters.

From block 1304, method 1300 may proceed to block 1306 which configures the simulation environment and loss function. The simulation environment may be configured based on the initial design of the photonic device, such as those illustrated in FIG. 10, including the excitation input regions and output regions and input excitation source values. The physical parameters which describe the photonic device may be mapped to structural parameters in the simulated environment. The loss function may also be defined using the target operational performance of the photonic device. The loss function may be defined in any way such that a loss metric can be determined to quantify the performance of the simulated physical device. The loss function may combine the target operational performance with other functions which determine metrics which might relate to other elements, such as fabricability of the device as determined by a minimum feature size constraint, for example. In general, any number of penalisation terms can be included in the loss function which act to influence the path of an optimisation procedure. The penalisation terms may further include the sensitivity to the fabrication model as determined by block 1314.

From block 1306, method 1300 may proceed to block 1308 which may apply a mean fabrication model transform to the initial design. The method may use a mean fabrication model to transform the structural parameters of the photonic device in the simulated environment to determine a set of as fabricated structural parameters which correspond to the average expected output of the physical device, using the fabrication model corresponding to the target fabrication process.

From block 1308, method 1300 may proceed to block 1310 which performs the operational simulation to determine the loss metric. The operational simulation of the photonic device described in the simulation environment may be performed such that after termination of the simulation, the loss metric may be determined using the output electromagnetic field values, structural parameters, and the loss function.

From block 1310, method 1300 may proceed to block 1312 which may perform an adjoint simulation to backpropagate the loss metric and determine gradients of the loss function. The method may use the field values from the operational simulation and the loss metric to define an adjoint simulation. The adjoint simulation is performed, which backpropagates the loss metric through the simulation to determine gradients of loss function with respect to the structural parameters, which can be subsequently backpropagated to determine gradients of the loss metric with respect to the physical parameters which describe the photonic device.

From block 1312, method 1300 may proceed to block 1314 where the sensitivity of the loss metric with respect to the fabrication model parameters (left-hand side of Equation 1) is calculated. Block 1314 calculates this sensitivity using the method 1200 outlined in FIG. 13, which uses the gradients of the loss metric with respect to the fabrication transformed structural parameters (second term of Equation 1) which may be determined using the adjoint method, as is calculated in block 1312. The calculated sensitivity of the loss metric with respect to fabrication model parameters (left-hand side of Equation 1) may either be subsequently included as an additional penalty term (albeit with no gradient being used for gradient-based optimisation) or combined in such a way that optimisation can proceed using gradients determined in block 1312 alongside the sensitivities determined in block 1314. For example, one way they can be combined is through thresholding the success criteria based on both the value of the loss metric and the sensitivity parameter value or through. The use of the sensitivity parameter, when not being used a simple penalty term, may be used to give an indication as to how robust a given design is to the fabrication model. This may be advantageous if a plurality of fabrication models are generated with similar loss metrics, which may indicate similar performance. The robustness of each model may be calculated using the sensitivity values, and then the model which is least sensitive (i.e. it is harder to change the loss metric with a variation of the physical parameters) may be chosen as it would be the most robust model.

From block 1314, method 1300 may proceed to decision block 1316 where a determination is made on whether the loss metric and/or sensitivity to the fabrication model has substantially converged such that the operational performance and target operational performance are within a threshold range, or the loss metric which potentially includes a plurality of additional constraints is below a threshold value. The decision may also factor in whether the sensitivity of the loss function to the fabrication model has reduced to a certain value or threshold. The threshold may be a percentage of the loss function. For example, it may be desired that the sensitivity of the loss function to the fabrication model is below 1%, although other values may be chosen, such as between 10% and 0.1%.

If the decision is NO, the method 1300 may proceed to block 1318 which revises the photonic device by updating the initial design. The revised physical parameters may be determined independently of the calculated gradients, or through utilisation of the gradients determined in block 1312 and/or the sensitivities determined in 1314. In some cases, the revised description may be generated through utilising an optimisation scheme together with a cycle of operational simulation, adjoint simulation and determination of the sensitivity to the fabrication model and a gradient and/or non-gradient-based optimisation algorithm, which could be gradient descent, for example. In other cases, another type of gradient and/or non-gradient-based optimisation scheme may be used to generate a revised set of physical parameters. The method then returns to block 1304 to receive the initial design parameters, which have now been updated, and target operational performance, and proceeds to block 1306. In general, iterative cycles of operational simulation, adjoint simulation, determination of the sensitivity to the fabrication model and revision of the physical parameters may be used until the convergence of loss metric and/or sensitivity to the fabrication model is substantial such that the decision at block 1316 exits under the YES condition.

If the decision at block 1314 is a YES, method 1300 may proceed to block 1320 which outputs the optimised design of the photonic device. It may output physical parameters corresponding to the design of the photonic device before termination of the method.

By using a mean fabrication model to simulate the average expected as fabricated photonic device, the inverse design method can include the average effect of the fabrication process, such that the optimisation is performed under conditions which are closely related to the actual observed conditions from that fabrication process. It therefore enables optimisation of a photonic device which is robust to the specific effects of that fabrication process. Furthermore, inclusion of the calculation of the sensitivity of the loss metric to the parameters of the fabrication model allow for a computationally efficient way to further determine how robust the current design parameters are to the effects encapsulated in the fabrication model. For example, the loss metric of a design with low sensitivity of the loss metric to the fabrication model parameters will not vary as much as the loss metric of a design with high sensitivity of the loss metric to the fabrication model parameters, upon the variation of the fabrication model parameters, indicating a more robust design. The information about the sensitivity to the fabrication model can then be used as part of the optimisation to guide optimisation towards a design which is robust, without the need to sample the fabrication model many times. The use of this method is facilitated by the fact that simulation happens on the as fabricated structural parameters, together with the adjoint method, being able to provide a gradient of the loss metric with respect to each as fabricated structural parameter. The fabrication model which has been defined in such as way to transform an initial set of structural parameters into the as fabricated structural parameters may then be directly used to determine changes in the output given small variations of the fabrication model parameters. Therefore, the information required to determine this sensitivity is obtained in only two EM simulations.

Although a mean fabrication model is used in method 1300 in a manner similar to method 1000, it may be the case that a plurality of fabrication models may be used, similar to method 1100, where performance metrics and gradients are determined for each fabrication model and then combined into a single loss metric value and single set of gradients for the physical parameters of the photonic device. The combination may be done by a simple statistical averaging. In other cases, the combination may be done using a softmin function (to preserve differentiability) or lower-bound function for a statistical distribution. In general, the combination may be done in any linear or non-linear way to reduce the set of loss metric values to a single loss metric value, and to reduce the sets of gradients of physical parameters to a single set of gradients of the physical parameters. Once these are determined, the sensitivity may then be determined as in block 1314. It is to be understood that this example may be adapted with components, configurations (and/or steps where a process or method is involved) and other features as presented in other examples herein. The adaption may be by addition, replacement. Existing features of this example may be removed. Correspondingly, it is to be understood that other examples herein may be adapted with components, configurations (and/or steps where a process or method is involved) and other features as presented in this example. Such features may include, but are not limited to any one or more of:
I. Any method can be used to perform the EM simulations to receive the computer modelled EM field output,
II. Any loss metric which enables the target performance to be included together with a potentially plurality of penalty terms as part of the optimisation can be used,
III. Any type of optimisation method/algorithm, which can be gradient or non-gradient based, can be used. In gradient-free optimisation, the adjoint simulation may not be required.
IV. Any method of sampling from the statistical model to define a particular fabrication model can be used,
V. Any method to combine the plurality of loss metrics and gradients, to give a single loss metric value and single set of gradients, can be used.

### Examples of Computer Systems for Use Herein

Some portions of the above description present the features of the invention in terms of process/methods/algorithms and symbolic representations of operations on information. These descriptions and representations are the means used by those skilled in the data processing arts to most effectively convey the substance of their work to others skilled in the art. These operations, while described functionally or logically, are understood to be implemented by computer programs. Furthermore, the reference to these arrangements of operations in terms of modules should not be considered to imply a structural limitation and references to functional names is by way of illustration and does not infer a loss of generality.

Unless specifically stated otherwise as apparent from the description above, it is appreciated that throughout the description, discussions utilising terms such as “processing” or “identifying” or “determining” or “displaying” or the like, refer to the action and processes of a computer system, or similar electronic computing device, that manipulates and transforms data represented as physical (electronic) quantities within the computer system memories or registers or other such information storage, transmission or display devices.

Certain aspects of the method or system may include process steps and instructions described herein in the form of an algorithm. It should be understood that the process steps, instructions, of the said method/system as described and claimed, may be executed by computer hardware operating under program control, and not mental steps performed by a human. Similarly, all of the types of data described and claimed may be stored in a computer readable storage medium operated by a computer system, and are not simply disembodied abstract ideas.

The method/system also relates to an apparatus for performing the operations herein. This apparatus may be specially constructed for the required purposes, or it may comprise a general-purpose computer selectively activated or reconfigured by a computer program stored on a computer readable medium that can be executed by the computer. Such a computer program is stored in a computer readable storage medium, such as, but not limited to, any type of disk including floppy disks, optical disks, CD-ROMs, magnetic-optical disks, read-only memories (ROMs), random access memories (RAMs), EPROMs, EEPROMs, magnetic or optical cards, application specific integrated circuits (ASICs), or any type of media suitable for storing electronic instructions, and each coupled to a computer system bus. Furthermore, the computers referred to in the specification may include a single processor or may be architectures employing multiple processor designs for increased computing capability.

The systems and methods may use one or more controller(s) that may take any suitable form. For instance, the controller(s) may comprise processing circuitry, including the one or more processors, and the memory devices comprising a single memory unit or a plurality of memory units. The memory devices may store computer program instructions that, when loaded into processing circuitry, control the operation of the route provider and/or route requester. The computer program instructions may provide the logic and routines that enable the apparatus to perform the functionality described above. The computer program instructions may arrive at the apparatus via an electromagnetic carrier signal or be copied from a physical entity such as a computer program product, a non-volatile electronic memory device (e.g. flash memory) or a record medium such as a CD-ROM or DVD. Typically, the processor(s) of the controller(s) may be coupled to both volatile memory and non-volatile memory. The computer program is stored in the non-volatile memory and may be executed by the processor(s) using the volatile memory for temporary storage of data or data and instructions. Examples of volatile memory include RAM, DRAM, SDRAM etc. Examples of non-volatile memory include ROM, PROM, EEPROM, flash memory, optical storage, magnetic storage, etc. The terms ‘memory’, ‘memory medium’ and ‘storage medium’ when used in this specification are intended to relate primarily to memory comprising both non-volatile memory and volatile memory unless the context implies otherwise, although the terms may also cover one or more volatile memories only, one or more non-volatile memories only, or one or more volatile memories and one or more non-volatile memories.

The algorithms and operations presented herein can be executed by any type or brand of computer or other apparatus. Various general-purpose systems may also be used with programs in accordance with the teachings herein, or it may prove convenient to construct more specialized apparatus to perform the required method steps. The required structure for a variety of these systems will be apparent to those of skill in the art, along with equivalent variations. In addition, the method/system is not described with reference to any particular programming language. It is appreciated that a variety of programming languages may be used to implement the teachings of the invention as described herein.

1. A computer system for outputting data for defining a component; the component for guiding electromagnetic waves;
the computer system comprising one or more modules configured to:
I) generate a fabrication process model using data measured from one or more outputs of a physical fabrication process suitable for forming the component;
II) generate at least a first model of the component and a second model of the component (6) by applying the fabrication process model to an initial configuration of the component (6); wherein:
i) the initial configuration of the component is associated with one or more physical parameter data values;
ii) the first and second models of the component each comprise one or more data values associated with the one or more physical parameter data values of the initial configuration;
iii) at least one of the said data values of the first model of the component is:
a) associated at least one of the physical parameter data values;
b) different to a corresponding data value, of the same physical parameter, of the second model of the component;
II) determine, for each of the first and second models of the component, a computer-modelled electromagnetic field output of the respective model for a given electromagnetic field input to the respective model of the component;
III) compare, for each of the first and second models of the component, the respective electromagnetic field output to a common pre-defined electromagnetic field output;
IV) output, based on comparing, data for defining the component; the output data associated with the physical parameters of the initial configuration of the component.

2. The computer system of claim 1 wherein a first set of models comprises the first and second models; the computer system is configured to:
a) determine, for each of the models of the component in the first set, a computer-modelled electromagnetic field output of the respective model for an electromagnetic field input to the respective model of the component; the electromagnetic field input being common for each of the models;
b) compare, for each of the models of the component in the first set, the respective electromagnetic field output to a common pre-defined electromagnetic field output;
c) output the data for defining the component based on the comparisons.

3. (canceled)

4. The computer system of claim 1 wherein the first model of the component and the second model are generated using a generic model of the component associated with the initial configuration, wherein the generic model of the component uses any one or more of:
i) the fabrication process model;
ii) outputs from the fabrication process model,
to produce the first and second models.

5-6. (canceled)

7. The computer system of claim 4 wherein the generic model is configured to output any of:
a) one or more graphical layouts of the component;
b) data defining the component of the respective model such that a module of the computer system may create a virtual version of the component in a virtual environment for EM simulation.

8. The computer system of claim 1 further configured to generate one or more test patterns for the physical fabrication process.

9. The computer system of claim 8 wherein the one or more test patterns are generated using a noise function.

10. The computer system of claim 1 and configured to generate the fabrication process model using a plurality of outputs from the physical fabrication process wherein:
a) each output is associated with a different test pattern;
b) each output comprises data of a measured shape of a physical feature of an output sample from the physical fabrication process.

11. The computer system of claim 1 and further configured such that the fabrication process model generates the first model and second model using component feature dimension data derived from the measured data.

12. The computer system of claim 1 wherein the fabrication process model is a model generated by machine learning wherein the fabrication process model is trained using the data measured from the one or more outputs of the physical fabrication process.

13. The computer system of claim 11 wherein the component feature dimension data comprises any one or more of:
a) a component dimension threshold;
b) a component dimension rule.

14. The computer system of claim 13 and configured to generate the component dimension rule from measured data.

15. The computer system of claim 13 wherein the data for defining the component is generated by:
a) generating, for each of the first and second model, a loss value based on the comparison to the common pre-defined electromagnetic field output;
b) generating the data for outputting, using the loss value, wherein the loss values are combined to generate a composite loss value.

16. (canceled)

17. The computer system of claim 15 wherein the composite loss value is used to:
a) generate the data for output; and/or,
b) select the data for output; and/or,
c) generate a further initial configuration of the component to, in turn, generate a further first and further second model of the component.

18. The computer system of claim 1 wherein the data for defining the component is generated using an inverse design process.

19-20. (canceled)

21. A computer implemented method for outputting data for defining a component; the component for guiding electromagnetic waves;
the method comprising using one or more computer modules to:
I) generate a fabrication process model using data measured from one or more outputs of a physical fabrication process suitable for forming the component;
II) generate at least a first model of the component and a second model of the component by applying the fabrication process model to an initial configuration of the component; wherein:
a) the initial configuration of the component is associated with one or more physical parameter data values;
b) the first and second models of the component each comprise one or more data values associated with the one or more physical parameter data values of the initial configuration;
c) at least one of the said data values of the first model of the component is:
a. associated at least one of the physical parameter data values;
b. different to a corresponding data value, of the same physical parameter, of the second model of the component;
II) determine, for each of the first and second models of the component, a computer-modelled electromagnetic field output of the respective model for a given electromagnetic field input to the respective model of the component;
III) compare, for each of the first and second models of the component, the respective electromagnetic field output to a common pre-defined electromagnetic field output;
IV) output, based on comparing, data for defining the component; the output data associated with the physical parameters of the initial configuration of the component.

22-24. (canceled)

25. A computer system for outputting data for defining a component; the component for guiding electromagnetic waves;
the computer system comprising one or more modules configured to:
I) generate a fabrication process model using data measured from one or more outputs of a physical fabrication process suitable for forming the component;
II) generate at least a first model of the component by applying the fabrication process model to an initial configuration of the component; wherein:
i) the initial configuration of the component is associated with one or more physical parameter data values;
ii) the first model of the component comprises one or more data values associated with the one or more physical parameter data values of the initial configuration;
iii) at least one of the said data values of the first model of the component is associated at least one of the physical parameter data values;
II) determine, for the first model of the component, a computer-modelled electromagnetic field output of the first model for a given electromagnetic field input to the first model;
III) compare, for the first model of the component, the respective electromagnetic field output to a pre-defined electromagnetic field output;
IV) output, based on comparing, data for defining the component; the output data associated with the physical parameters of the initial configuration of the component,
wherein the computer system is further configured to:
i) determine a plurality of physical parameter data values for a physical parameter of the initial configuration;
ii) determine an average value of the plurality of physical parameter data values for the physical parameter; and
iii) use the average value to generate the first model of the component.

26-27. (canceled)

28. A computer implemented method for outputting data for defining a fabrication process model for defining a component made in a fabrication process; the component for guiding electromagnetic waves;
the method comprising using one or more computer modules to:
receive a plurality of fabrication process models, wherein each of the plurality of fabrication process models comprises a set of one or more associated fabrication process model parameter data values, wherein each of the plurality of the fabrication process models is represented by a parameter space by its respective set of one or more fabrication process model parameter data values;
perform principal component analysis on the one or more sets of fabrication process model parameter data values to determine at least a first principal component, wherein the first principal component corresponds to a direction in the parameter space comprising a largest variance;
determine a distribution of fabrication process model parameter data values along the at least first principal component;
sample the distribution of fabrication process model parameter data values along at least a first principal axis to obtain at a plurality of samples of sets of fabrication process model parameter data values;
output data representing the plurality of samples of sets of fabrication process model parameter data values.

29-33. (canceled)

34. The computer implemented method of claim 28, wherein the method further comprises determining at least an Nth principal component, wherein the Nth principal component corresponds to a direction in the parameter space which has a Nth largest variance, wherein a maximum value of N corresponds to a number of fabrication process model parameter data values used to define the fabrication process model, wherein the direction of the Nth principal component is orthogonal to the first principal component and wherein the method further comprises sampling along a subset of the N principal components.

35-42. (canceled)

43. The computer implemented method of claim 28, wherein the output data is used to define a fabrication process model for use in an inverse design method for optimising a photonic component.

44. The computer system of claim 15, wherein the comparison further comprises determining a sensitivity of the composite loss value with respect to the fabrication model parameters.

45. The computer implemented method of claim 28, wherein the fabrication process model parameter data values are representative of physical parameters of the component, or are representative of computational parameters defining either a kernel, or weights in a neural network.
